(19) United States
(12) Patent Application Publication
(10) Pub. No.: US 2023/0124192 A1
(43) Pub. Date: Apr. 20, 2023

(54) HEATING AND COOLING SYSTEMS FOR EDGE DATA CENTERS

(71) Applicants: Kevin Liedtke, Portland, OR (US); Patrick Connor, Beaverton, OR (US); James Hearn, Portland, OR (US); Francesc Guim Bernat, Barcelona (ES); Mark MacDonald, Beaverton, OR (US)

(72) Inventors: Kevin Liedtke, Portland, OR (US); Patrick Connor, Beaverton, OR (US); James Hearn, Portland, OR (US); Francesc Guim Bernat, Barcelona (ES); Mark MacDonald, Beaverton, OR (US)

(21) Appl. No.: 18/069,751

(22) Filed: Dec. 21, 2022

(51) Int. Cl. F24T 50/00; H05K 7/20; F24T 10/10

(52) U.S. Cl. CPC F24T 50/00; H05K 7/20236; H05K 7/20836; H05K 7/20763; F24T 10/10

(57) ABSTRACT

Example heating and cooling systems for edge data centers are disclosed herein. A system disclosed herein includes a subterranean vault to be disposed at least partially below ground level an of environment, an edge data center in the subterranean vault, and a geothermal heat pump system to regulate a temperature of ambient air in the subterranean vault.

### FIELD OF THE DISCLOSURE

This disclosure relates generally to edge data centers and, more particularly, to heating and cooling systems for edge data centers.

### BACKGROUND

Edge computing devices are typically mounted on the side of a cell tower or located at the base of a cell tower. As such, these devices exposed to the high and low temperatures of their surrounding environments.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17 illustrates an overview of an edge cloud configuration for edge computing.

FIG. 18 illustrates an example system including an example edge data center and an example subterranean vault for housing the example edge data center.

FIG. 19 illustrates the example system of FIG. 18 including an example geothermal heat pump system to regulate the temperature inside the example subterranean vault.

FIG. 20 illustrates an example in which the example geothermal heat pump system of FIG. 19 is implemented as an open loop system.

FIG. 21 illustrates the example geothermal heat pump system of FIG. 19 having multiple example ground loops.

FIG. 22 illustrates the example system of FIG. 19 including an example secondary circuit to route fluid to one or more example edge servers.

FIG. 23 is a perspective view of the example subterranean vault of FIG. 19 having an example ground loop on an exterior side of the example subterranean vault.

FIG. 24 illustrates an example system including an example supplemental geothermal heat pump system to provide additional fluid flow to one or more example edge data centers.

FIG. 25 illustrates an example system including an example heating or cooling system that utilizes a public utility line as an example heat sink for the example system.

FIG. 26 is a flowchart representative of example machine readable instructions and/or example operations that may be executed by example processor circuitry to implement example control circuitry of FIG. 19.

FIG. 27 is a block diagram of an example processing platform including processor circuitry structured to execute the example machine readable instructions and/or the example operations of FIG. 26 to implement the example control circuitry of FIG. 19.

FIG. 28 is a block diagram of an example implementation of the processor circuitry of FIG. 27.

FIG. 29 is a block diagram of another example implementation of the processor circuitry of FIG. 27.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

In recent years, more and more digital content and computing power is being migrated to edge data centers. Edge data centers take on workloads previously handled at remote data centers. This enables the content and computing resources to be located closer to the end users, which reduces latency, decreases backhaul network loads, and improves user experience. These edge data centers typically include one or more edge servers or other computing devices that are mounted on cell towers or located in sheds at the base or foot of a cell tower. As such, the edge servers are often located outdoors and are therefore subject to extreme temperature ranges. Keeping the edge server hardware in an operational temperature range to ensure proper functionality can be costly and generally requires dedicated heating and/or cooling equipment. In some instances, a fan is used to blow air across the edge servers to help cool the edge servers. However, these known systems may be insufficient to ensure proper heating and/or cooling, especially in extreme temperature environments (e.g., +100° F., −20° F.). Further, as workloads increase, the cooling requirements increase. If the thermal workloads are not properly handled, it can result in workloads being throttled, rescheduled, or transferred (e.g., transferred to a remote data center or a less congested edge node), which results in unnecessary workload transitions and longer latencies for the transferred workloads.

Disclosed herein are example subterranean vaults that can be at least partially buried in the ground and used to house the edge servers of an edge data center. The temperature below ground level (e.g., a few meters below ground) is relatively constant and mild compared to the air temperature above ground. For example, in higher temperature environments, the temperature of the air above ground may be 90-120° F. (32-49° C.), while the temperature of the ground a few meters below the ground surface may be about 70° F. (21° C.). Conversely, in lower temperature environments, the ground is warmer than the atmospheric air and can be used to help warm the edge servers in the subterranean vault. Therefore, housing the edge servers in a vault below ground helps maintain the edge servers in a more stable and mild temperature range (e.g., 60-80° F.) that promotes operational efficiency. In some examples, the vault with the edge data center is buried in the ground near the base or foot of a cell tower. Power lines, signal lines, wireless antennas, and/or MAN/WAN wired networks can be routed to the underground vault.

Also disclosed herein are example heating and cooling systems, such as geothermal heat pump systems, that can be used to regulate the temperature of the air inside the subterranean vault. An example geothermal heat pump system includes a pump, a radiator in the subterranean vault, a ground loop that is buried in the ground, and a fluid circuit that fluidly couples the pump, the radiator, and the ground loop. During operation, fluid (e.g., water, coolant, etc.) is pumped through the ground loop, which cools or warms the fluid to the temperature of the ground. The fluid is then pumped through the radiator to heat or cool the air in the subterranean vault. As such, the example system takes advantage of the constant temperature of the earth to maintain the edge servers in an optimal temperature for computing efficiency. Geothermal heat pump systems are highly efficient, especially compared to air exchange heat pumps or gas furnaces. In some examples, the geothermal heat pump system is configured as a closed loop system, which cycles the same fluid (e.g., water, oil, refrigerant, gasoline, hydrogen). In other examples, the geothermal heat pump system can be configured as an open loop system, which utilizes water from body of water (e.g., a well, a lake, a pond, etc.).

Also disclosed herein is an example heating or cooling system for an edge data center that has a primary heat exchange loop tied into a public utility line, such as a public water main. In particular, the system includes a liquid-to-liquid heat exchanger between the system loop and the public water main. Waste heat from the edge data center is transferred to the water in the public water main, thereby cooling the edge data center. The heat exchanger is hermetically sealed or impermeably sealed to keep the system liquid separate from the water. Any increase in temperature to the water of the public water main is relatively small (e.g., less than 9° F. (5° C.) increase), and would quickly cool back to the ground temperature before reaching any downstream locations.

As noted above, the use of liquids to cool electronic components is being explored for its benefits over more traditional air cooling systems, as there are increasing needs to address thermal management risks resulting from increased thermal design power in high performance systems (e.g., CPU and/or GPU servers in data centers, accelerators, artificial intelligence computing, machine learning computing, cloud computing, edge computing, and the like). More particularly, relative to air, liquid has inherent advantages of higher specific heat (when no boiling is involved) and higher latent heat of vaporization (when boiling is involved). In some instances, liquid can be used to indirectly cool electronic components by cooling a cold plate that is thermally coupled to the electronic component(s). An alternative approach is to directly immerse electronic components in the cooling liquid. In direct immersion cooling, the liquid can be in direct contact with the electronic components to directly draw away heat from the electronic components. To enable the cooling liquid to be in direct contact with electronic components, the cooling liquid is electrically insulative (e.g., a dielectric liquid).

A liquid cooling system can involve at least one of single-phase cooling or two-phase cooling. As used herein, single-phase cooling (e.g., single-phase immersion cooling) means the cooling fluid (sometimes also referred to herein as cooling liquid or coolant) used to cool electronic components draws heat away from heat sources (e.g., electronic components) without changing phase (e.g., without boiling and becoming vapor). Such cooling fluids are referred to herein as single-phase cooling fluids, liquids, or coolants. By contrast, as used herein, two-phase cooling (e.g., two-phase immersion cooling) means the cooling fluid (e.g., cooling liquid) vaporizes or boils from the heat generated by the electronic components to be cooled, thereby changing from the liquid phase to the vapor phase (e.g., gaseous). The gaseous vapor may subsequently be condensed back into a liquid (e.g., via a condenser) to again be used in the cooling process. Such cooling fluids are referred to herein as two-phase cooling fluids, liquids, or coolants. Notably, gases (e.g., air) can also be used to cool components and, therefore, may also be referred to as a cooling fluid and/or a coolant. However, indirect cooling and immersion cooling typically involves at least one cooling liquid (which may or may not change to the vapor phase when in use). Example systems, apparatus, and associated methods to improve cooling systems and/or associated cooling processes are disclosed herein.

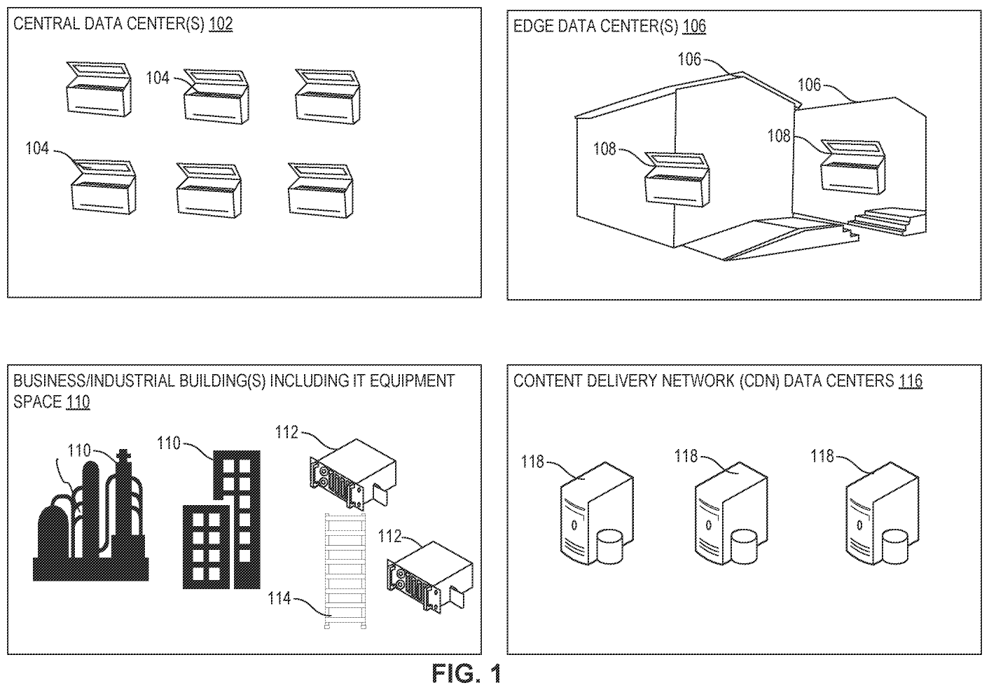

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase cooling or two-phase cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed (e.g., positioned, located, arranged, etc.) in immersion cooling tank(s) such as the immersion tanks 104, 108 shown in connection with the data centers 102, 106.

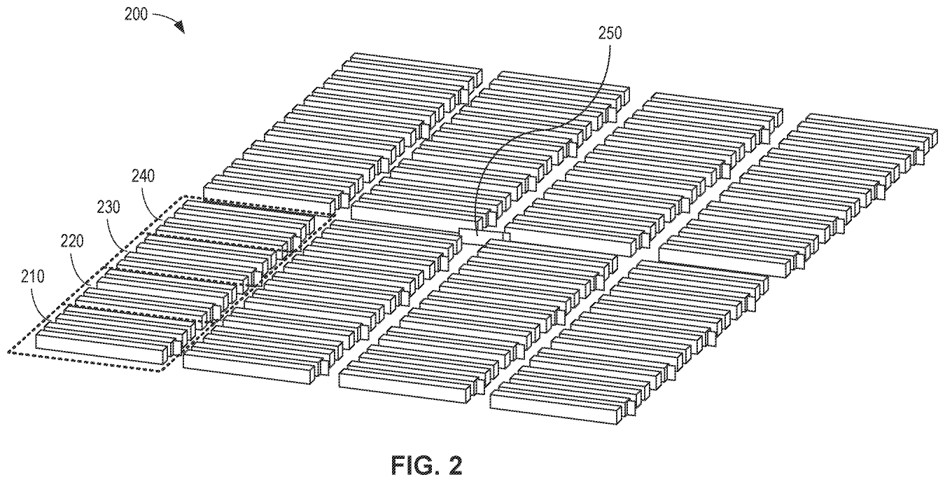

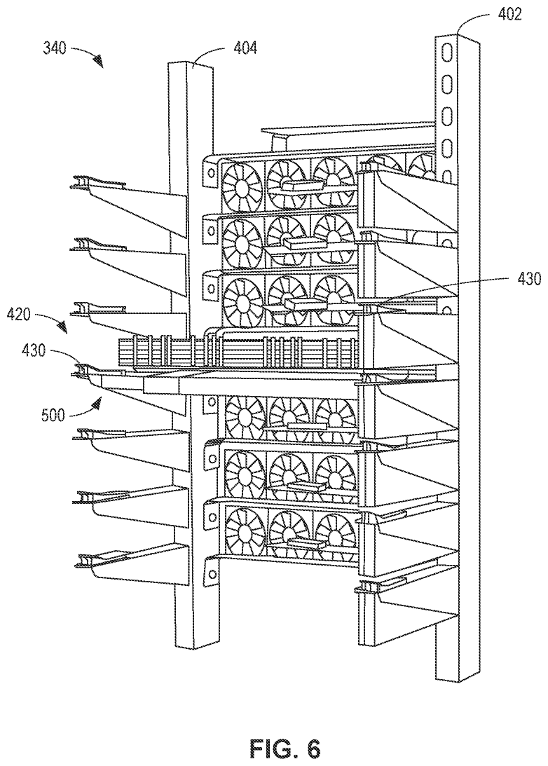

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a high-speed fabric (e.g., Omni-Path™ Infiniband, Ethernet) technology. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage, and perhaps additional resources in a single chassis. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

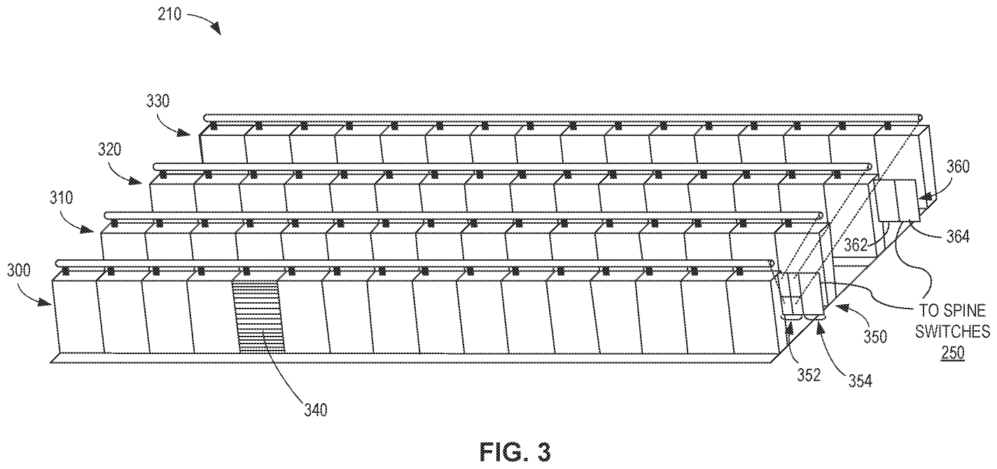

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

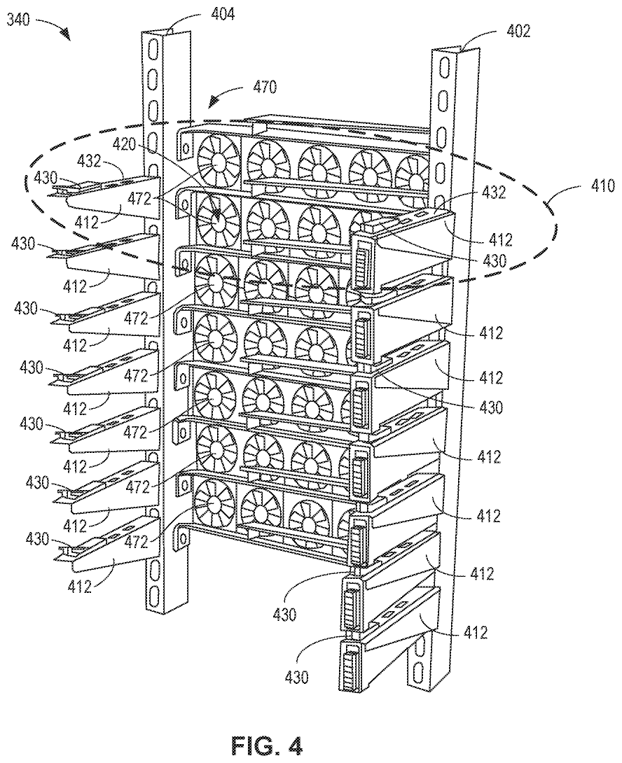

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

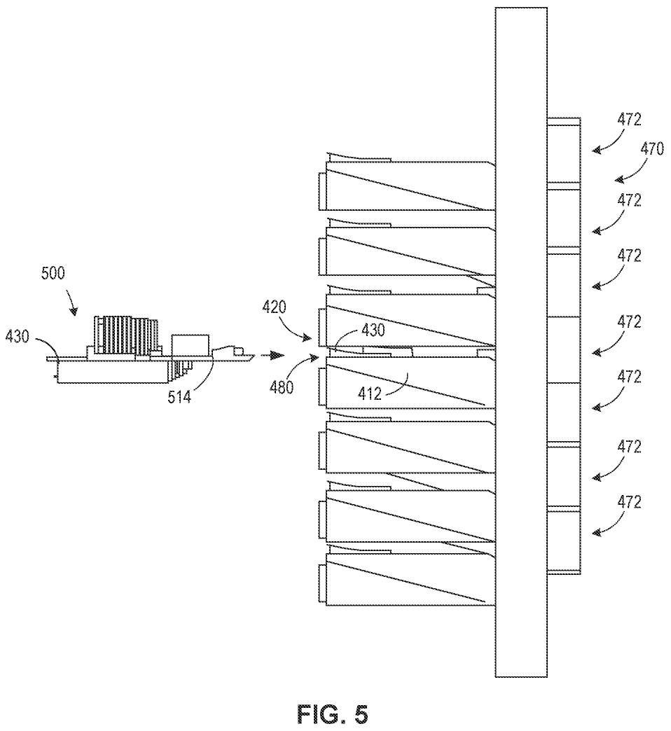

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

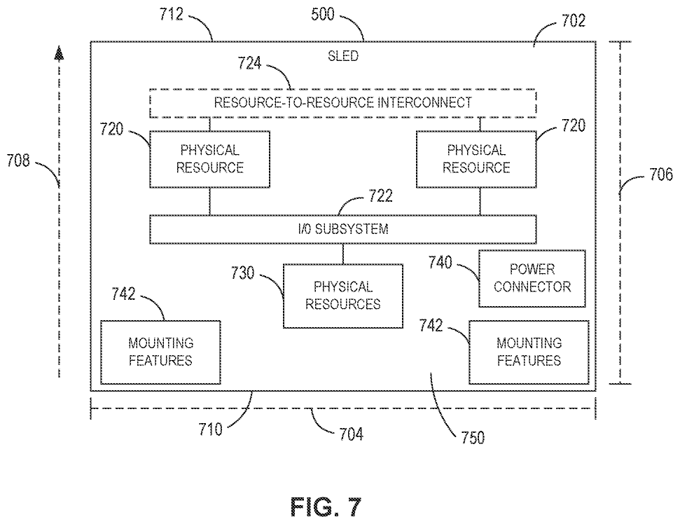

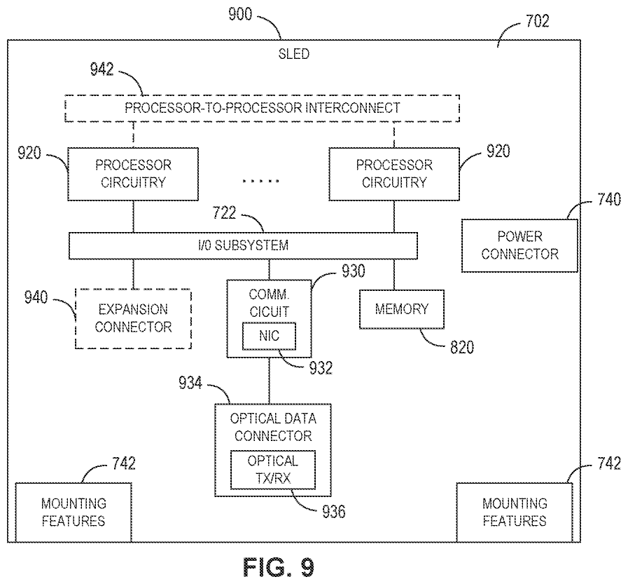

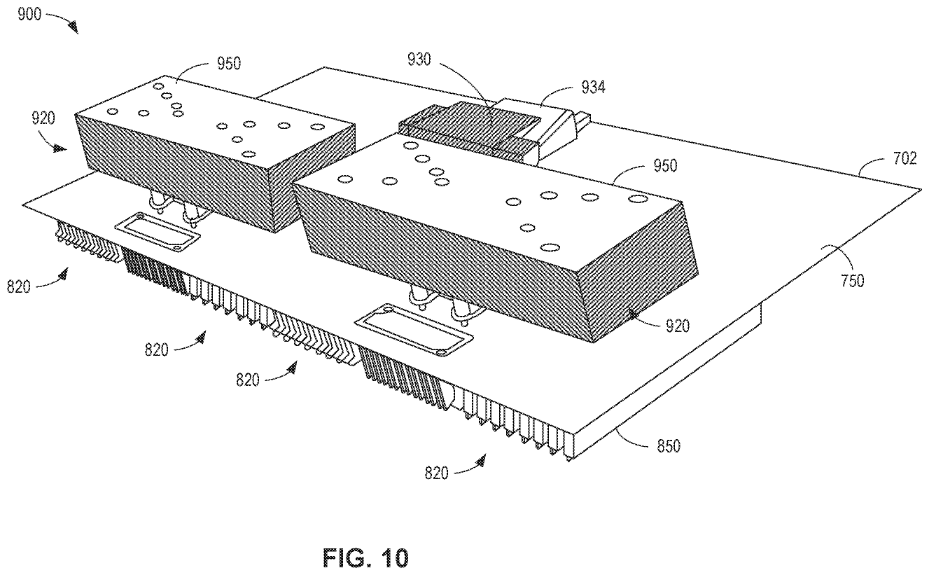

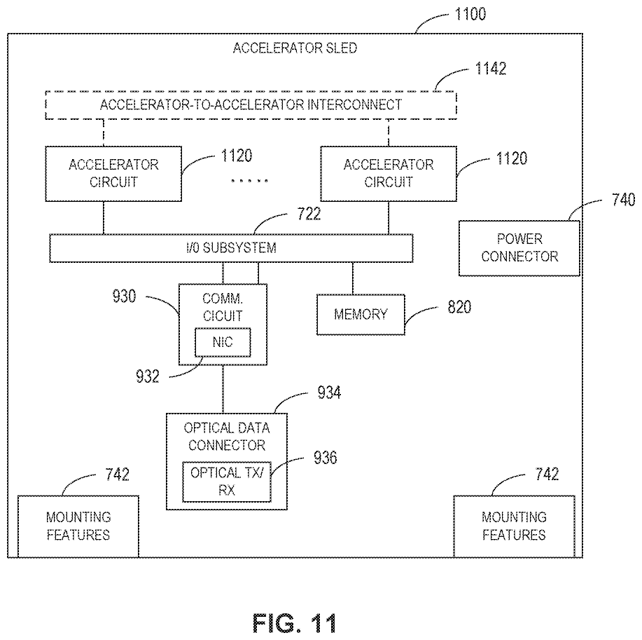

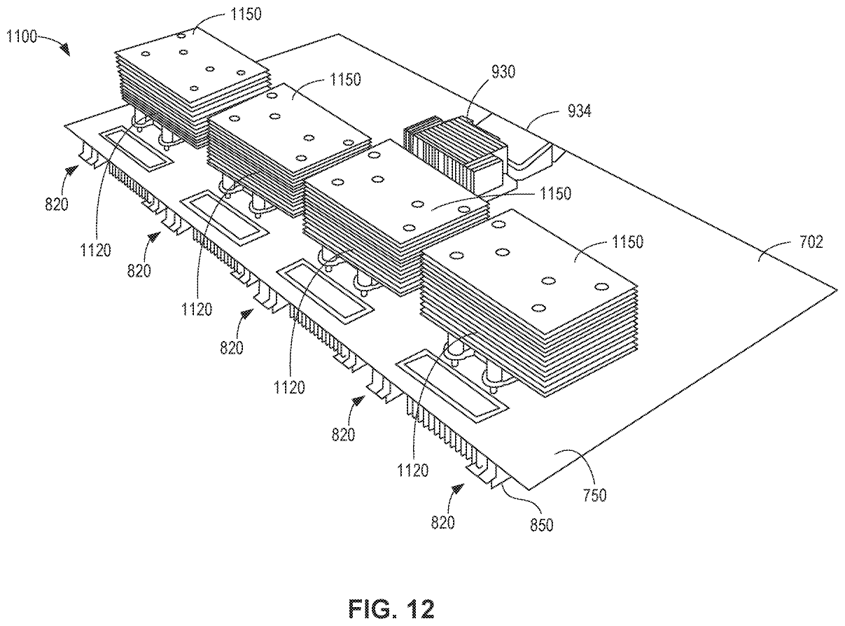

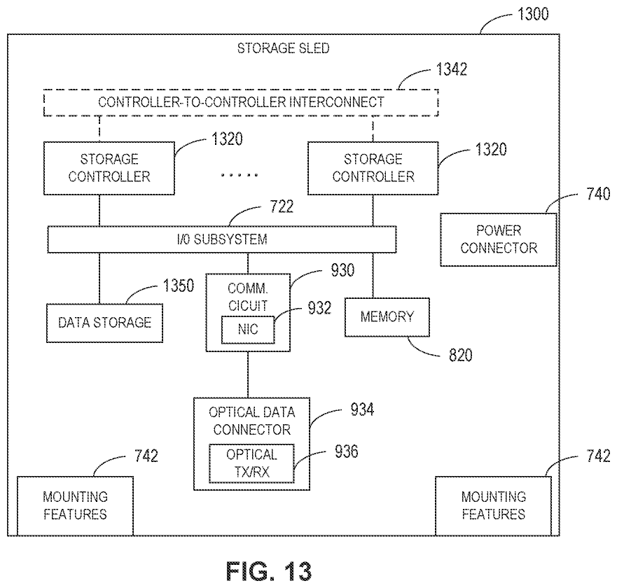

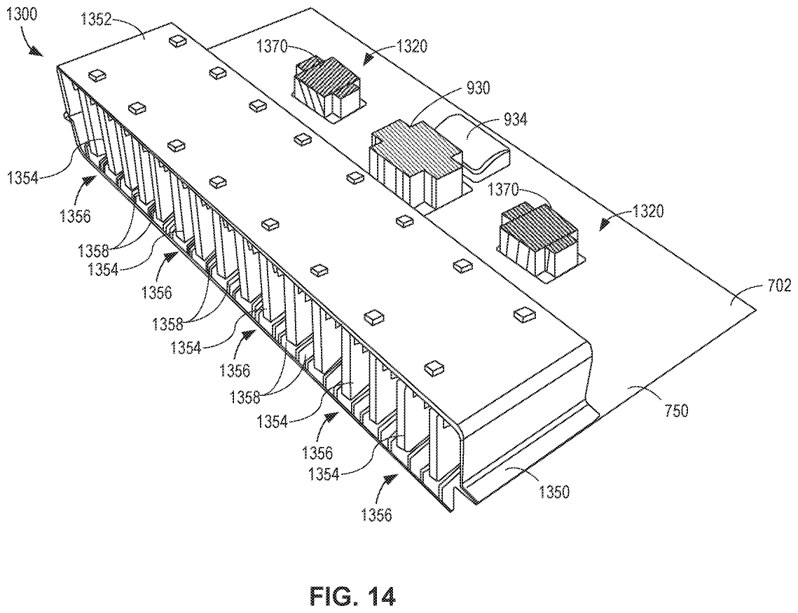

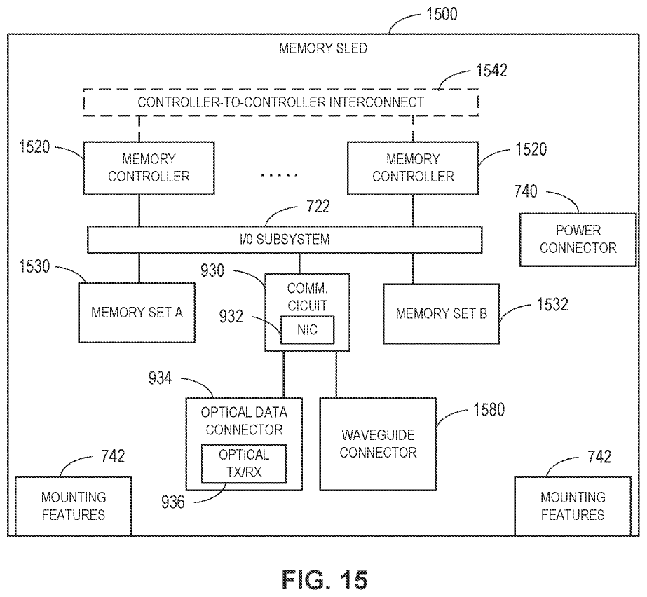

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus, a DDR5 data bus, or another system host memory architecture.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

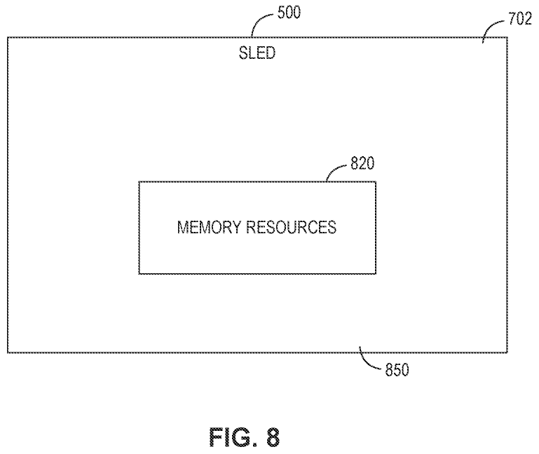

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

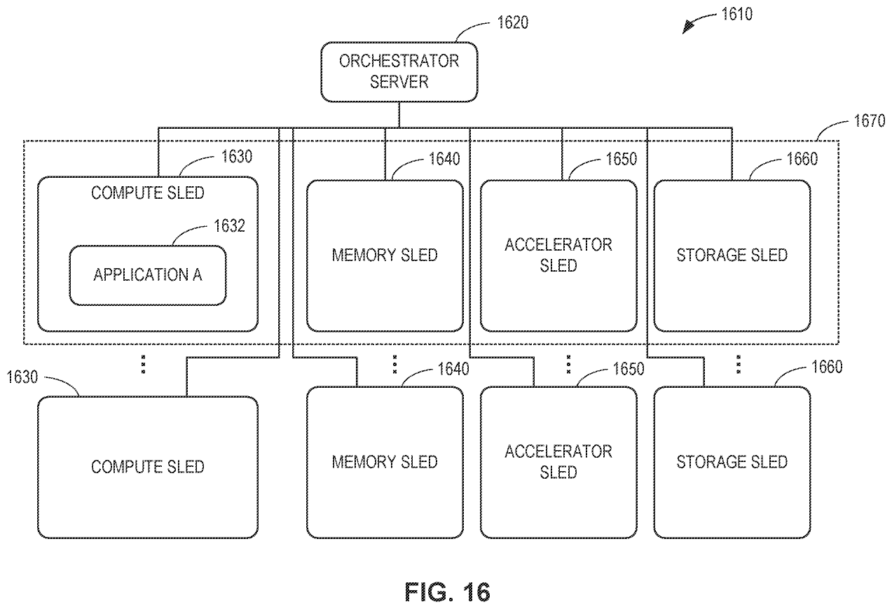

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

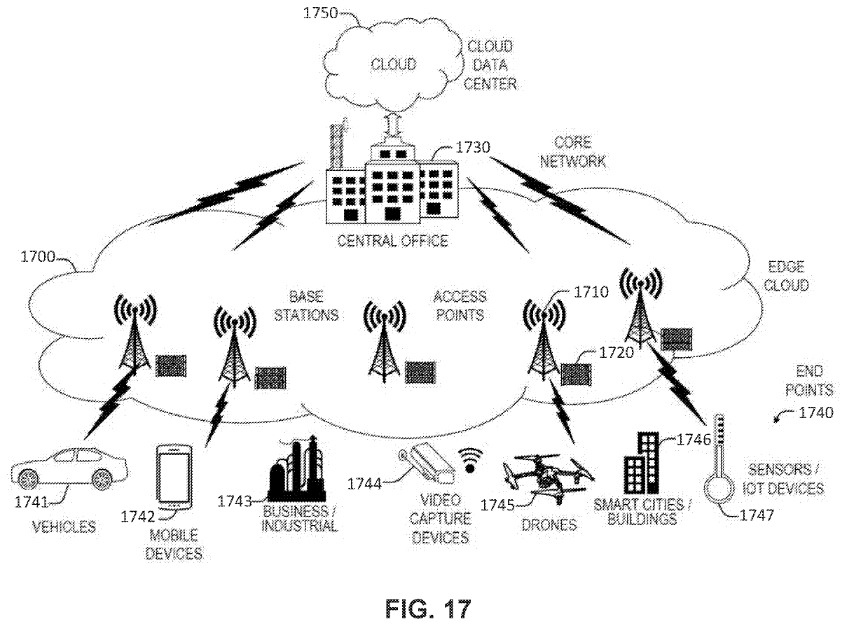

FIG. 17 is a block diagram 1700 showing an overview of a configuration for Edge computing, which includes a layer of processing referred to in many of the following examples as an “Edge cloud”. As shown, the Edge cloud 1700 is co-located at an Edge location, such as an access point or base station 1710, a local processing hub 1720, or a central office 1730, and thus may include multiple entities, devices, and equipment instances. The Edge cloud 1700 is located much closer to the endpoint (consumer and producer) data sources 1740 (e.g., autonomous vehicles 1741, user equipment 1742, business and industrial equipment 1743, video capture devices 1744, drones 1745, smart cities and building devices 1746, sensors and IoT devices 1747, etc.) than the cloud data center 1750. Compute, memory, and storage resources which are offered at the edges in the Edge cloud 1700 are critical to providing ultra-low latency response times for services and functions used by the endpoint data sources 1740 as well as reduce network backhaul traffic from the Edge cloud 1700 toward cloud data center 1750 thus improving energy consumption and overall network usages among other benefits.

Compute, memory, and storage are scarce resources, and generally decrease depending on the Edge location (e.g., fewer processing resources being available at consumer endpoint devices, than at a base station, than at a central office). However, the closer that the Edge location is to the endpoint (e.g., user equipment (UE)), the more that space and power is often constrained. Thus, Edge computing attempts to reduce the amount of resources needed for network services, through the distribution of more resources which are located closer both geographically and in network access time. In this manner, Edge computing attempts to bring the compute resources to the workload data where appropriate, or bring the workload data to the compute resources.

The following describes aspects of an Edge cloud architecture that covers multiple potential deployments and addresses restrictions that some network operators or service providers may have in their own infrastructures. These include, variation of configurations based on the Edge location (because edges at a base station level, for instance, may have more constrained performance and capabilities in a multi-tenant scenario); configurations based on the type of compute, memory, storage, fabric, acceleration, or like resources available to Edge locations, tiers of locations, or groups of locations; the service, security, and management and orchestration capabilities; and related objectives to achieve usability and performance of end services. These deployments may accomplish processing in network layers that may be considered as “near Edge”, “close Edge”, “local Edge”, “middle Edge”, “far Edge”, or “Fog” layers, depending on latency, distance, and timing characteristics.

Edge computing is a developing paradigm where computing is performed at or closer to the “Edge” of a network, typically through the use of a compute platform (e.g., x86, RISC-V, or ARM compute hardware architecture) implemented at base stations, gateways, network routers, or other devices which are much closer to endpoint devices producing and consuming the data. For example, Edge gateway servers may be equipped with pools of memory and storage resources to perform computation in real-time for low latency use-cases (e.g., autonomous driving or video surveillance) for connected client devices. Or as an example, base stations may be augmented with compute and acceleration resources to directly process service workloads for connected user equipment, without further communicating data via backhaul networks. Or as another example, central office network management hardware may be replaced with standardized compute hardware that performs virtualized network functions and offers compute resources for the execution of services and consumer functions for connected devices. Within Edge computing networks, there may be scenarios in services which the compute resource will be “moved” to the data, as well as scenarios in which the data will be “moved” to the compute resource. Or as an example, base station compute, acceleration and network resources can provide services in order to scale to workload demands on an as needed basis by activating dormant capacity (subscription, capacity on demand) in order to manage corner cases, emergencies or to provide longevity for deployed resources over a significantly longer implemented lifecycle.

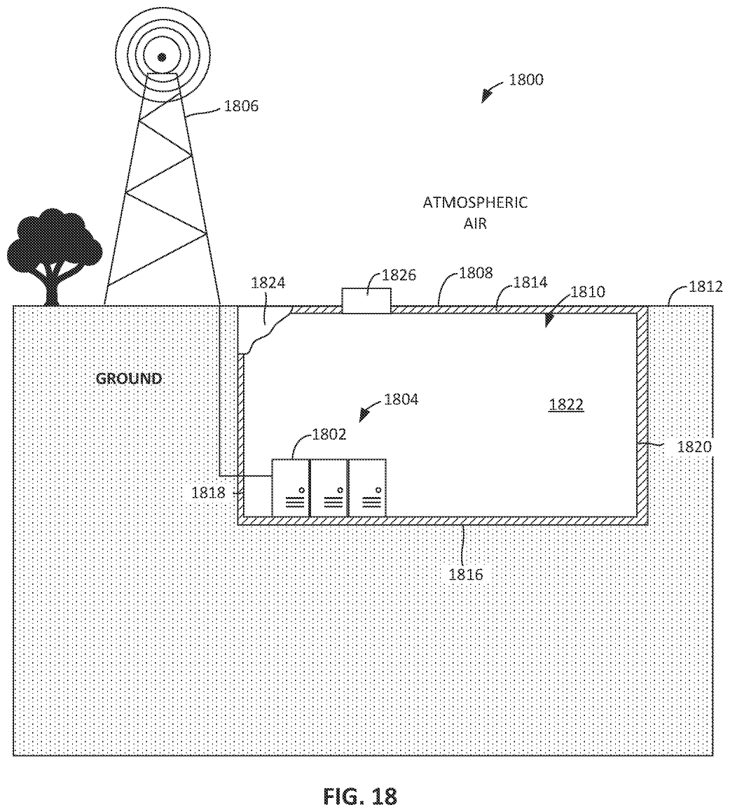

FIG. 18 illustrates an example system 1800 for housing and regulating the temperature of one or more example edge servers 1802 of an example edge data center 1804. The edge data center 1804 can include any number of edge servers 1802 (e.g., one, two, three, etc.), including any of the example devices disclosed above in connection with FIGS. 2-16. The edge data center 1804 provides content delivery and compute resources to users in the area, as disclosed above. In the illustrated example, the edge data center 1804 is located near the base of an example cell tower 1806, which typically provides the most reliable reception for communicating with the end user and/or remote data centers. However, in other examples, the edge data center 1804 may not be located near a cell tower.

In the illustrated example, the system 1800 includes a subterranean vault 1808 to house the edge data center 1804. The subterranean vault 1808 is a structural housing, container, or enclosure that defines an internal area 1810 (e.g., a cavity). The edge servers 1802 (and other temperature sensitive equipment) of the edge data center 1804 are disposed (e.g., positioned, located, arranged, etc.) in the internal area 1810 of the subterranean vault 1808. The subterranean vault 1808 is to be disposed at least partially below ground level 1812 of an environment. As such, the subterranean vault 1808 is at least partially disposed (e.g., buried) in the ground material (e.g., soil, rock, clay, etc.). The temperature of the soil (or other material) in the ground is relatively mild and stable compared to the temperature of the atmospheric air above ground. Therefore, the temperature of the ambient air inside the subterranean vault 1808 is much more stable. This helps maintain the edge servers 1802 at a preferred operating temperature (e.g., 60-80° F.). For example, in a hot environment, the atmospheric air above the ground level 1812 may be 100° F. (38° C.), while the temperature of the soil 5-10 feet down is about 75° F. (24° C.). Conversely, in a relatively cold environment, the atmospheric air above ground may be −10° F. (−23° C.), while the temperature of the of the solid 5-10 feet down is about 45° F. (7° C.). Therefore, the inside of the subterranean vault 1808 remains closer to a preferred or more stable temperature for the edge servers 1802 and/other electronic devices of the edge data center 1804.

The subterranean vault 1808 may include a plurality of walls. In this example, the subterranean vault 1808 is cuboid shaped and has six walls, including a top wall 1814, a bottom wall 1816, and four side walls 1818, 1820, 1822, 1824. A portion of the fourth wall 1824 has been removed to expose the internal area 1810 of the subterranean vault 1808. The walls 1814-1824 define the internal area 1810 where the edge servers 1802 and other equipment of the edge data center 1804 are housed. In other examples, the subterranean vault 1808 can have a different shaped construction (e.g., a sphere, a pyramid, etc.). The walls 1814-1824 of the subterranean vault 1808 can be constructed of any material. In some examples, the walls 1814-1824 of the subterranean vault 1808 are constructed of a thermally conductive material, such as metal (e.g., steel), to enable heat transfer between the internal area 1810 and the soil in the ground. In other examples, the walls 1814-1824 of the subterranean vault 108 can be constructed of another material, such as concrete or plastic. In some examples, the subterranean vault 1808 includes a hatch or access port 1826 that is at least partially above ground. The hatch 1826 enables a person to access the interior area 1810 for maintenance, upgrades, and/or other reasons. In some examples, antennas and/or other equipment may be disposed (e.g., positioned, located, arranged, etc.) in the hatch 1826 for easy access. The hatch 1826 can also provide venting for fresh air into the subterranean vault 1808. In this example, the hatch 1826 is defined in the top wall 1814. Additionally or alternatively, the subterranean vault 1808 can include one or more doors or openings in one of the others walls 1816-1824.

In the illustrated example, the subterranean vault 1808 is disposed in the ground such that the top wall 1814 is about even or aligned with the ground level 1812, and the bottom wall 1816 and the side walls 1820-1824 are in contact with the soil in the ground. As disclosed above, the temperature of the soil in the ground is relatively mild and stable compared to the atmospheric temperature above ground, which helps regulate the temperature inside the internal area 1810 of the subterranean vault 1808. In other examples, the subterranean vault 1808 can be disposed further into the ground (e.g., 10 feet), such that the top wall 1814 is below the ground level 1812.

In some examples, a hole is dug in the ground and the subterranean vault 1808 is constructed in the hole in the ground, such as by pouring concrete into the hole in the ground. In other examples the subterranean vault 1808 is pre-constructed as a housing that is lowered (e.g., via a crane) into the hole in the ground and buried. In some examples, the edge data center 1804 and the other devices in the subterranean vault 1808 are pre-installed in the subterranean vault 1808, such that the entire subterranean vault 1808 is constructed as a unit that is then installed in the hole in the ground.

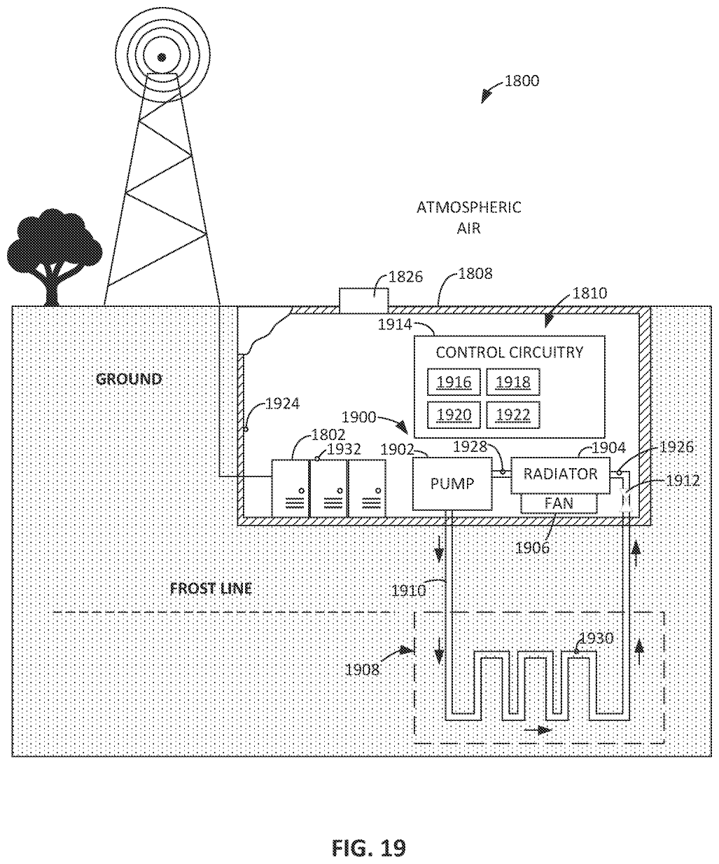

In some examples, the system 1800 can include a heating or cooling system to regulate or control the temperature of the ambient air in the subterranean vault 1808. For example, FIG. 19 shows an example in which the system 1800 includes a geothermal heat pump system 1900 (which may also be referred to as a ground source heat pump system, a geothermal heat transfer loop, or a temperature control system). The geothermal heat pump system 1900 can be used to heat and/or cool the ambient air in the subterranean vault 1808, depending on the atmospheric air temperature and desired temperature inside the subterranean vault 1808. As such, the geothermal heat pump system 1900 helps maintain the temperature of the air in the subterranean vault 1808 at a preferred operating temperature (or range) for increased (e.g., maximum) efficiency of the edge servers 1802. The geothermal heat pump system 1900 utilizes the temperature of the ground to provide heating and/or cooling, as disclosed in further detail herein.

In the illustrated example, the geothermal heat pump system 1900 includes an example pump 1902 (which may also be referred to as a compressor), an example radiator 1904, an example fan 1906, an example ground loop 1908 (sometimes referred to as a geothermal loop), and an example fluid circuit 1910. The fluid circuit 1910 fluidly couples the pump 1902, the radiator 1904, and the ground loop 1908. The fluid circuit 1910 can include any type and/or number of fluid lines (e.g., hoses, tubes), fluid channels, connectors, valves, and/or a system of the foregoing that fluidly couple the components. The fluid circuit 1910 contains a fluid, which may be a liquid or gas or combination of liquid and gas. In some examples, the fluid is water. In other examples, the fluid circuit 1910 can include another type of fluid, such as oil, a glycol/water solution, a dielectric fluid, a coolant or refrigerant, gasoline, a gas other than natural gas, such as hydrogen, etc. The fluid may be a single phase or two phase liquid. The fluid circuit 1910 includes a continuous flow of fluid. In some examples, the geothermal heat pump system 1900 includes a reservoir of additional fluid. In the illustrated example, the pump 1902, the radiator 1904, and the fan 1906 are disposed (e.g., positioned, located, arranged, etc.) in the subterranean vault 1808. In other examples, the pump 1902 can be disposed outside of the subterranean vault 1808. The ground loop 1908 is a portion of the fluid circuit 1910 that is disposed (e.g., buried) in the ground. The ground loop 1908 enables heat transfer between the fluid in the fluid circuit 1910 and surrounding ground material (e.g., soil, clay, rock, water, etc.).

As an example of operation, assume the atmospheric air is relatively warm (e.g., +100° F. (38° C.) and it is therefore desired to cool the internal area 1810 of the subterranean vault 1808. The geothermal heat pump system 1900 can be activated by activating the pump 1902. The pump 202 drives the fluid through the fluid circuit 1910 to the ground loop 1908. As the fluid flows through the ground loop 1908, the fluid is cooled to a temperature that is at or near the ground temperature (e.g., 75° F. (24° C.)). The cooled fluid then flows through the radiator 1904. The radiator 1904 absorbs heat from the air in the internal area 1810, thereby reducing (cooling) the ambient temperature in the internal area 1810 of subterranean vault 1808. In some examples the fan 1906 can be activated to increase air flow across the radiator 1904 and thereby increase this heat transfer effect. The warmed fluid is then pumped back into the ground loop 1908 and the cycle repeats. As such, the geothermal heat pump system 1900 cools the inside of the subterranean vault 1808 to maintain the temperature at or near a preferred operating temperature (or range) for the edge servers 1802.

Conversely, assuming the atmospheric air is relatively cold (e.g., −10° F. (−23° C.)), the geothermal heat pump system 1900 can be operated in a similar manner to increase or warm the temperature of the ambient air in the subterranean vault 1808. In such an example, as the fluid flows through the ground loop 1908, the fluid is warmed by the surrounding ground temperature. The heated fluid flows through the radiator 1904, which dissipates the heat to the surrounding air in the subterranean vault 1808, thereby increasing (warming) the air in the internal area 1810. In some examples, the fan 1906 can be activated to direct ambient air across the radiator 1904 to increase this heat transfer effect. The cooled liquid is then pumped back into the ground loop 1908 and the cycle repeats. Therefore, the example geothermal heat pump system 1900 can be used to regulate the temperature inside of the subterranean vault 1808. The pump 1902 can be activated, deactivated, and/or the speed can be adjusted to regulate the amount of heating or cooling. In this example, the flow of fluid is counter-clockwise in FIG. 19. However, the pump 1902 can be reversed such that the flow of fluid is in the opposite direction.

In some examples, the radiator 1904 is disposed in the internal area 1810 of the subterranean vault 1808 to condition the ambient air already in the subterranean vault 1808. Additionally or alternatively, the radiator 1904 can condition incoming air (e.g., fresh air) as existing air is vented to the atmosphere. For example, the radiator 1904 may be disposed below the hatch 1826 to condition incoming air. In some examples, the system 1800 includes a duct to route the incoming air from the hatch 1826 (and/or other vent) to the radiator 1904. In some examples, the air in the subterranean vault 1808 may be vented or recirculated based on measurements of the temperature inside the subterranean vault 1808 versus the temperature of the atmospheric air outside the subterranean vault 1808.

In some examples, the fluid (e.g., water) in the fluid circuit 1910 may only be capable of being heated or cooled to the temperature of the ground surrounding the ground loop 1908. As such, the geothermal heat pump system 1900 is only capable of heating or cooling the air in the subterranean vault 1808 to the ground temperature. However, in other examples, the fluid can be implemented as a refrigerant (e.g., R-407C, R-410A, and R-134a), and the geothermal heat pump system 1900 can include an expansion valve 1912 coupled to the fluid circuit 1910. This enables the fluid to reach temperatures that are higher or lower than the ground temperature. As such, the geothermal heat pump system 1900 can provide improved heating or cooling to the internal area 1810 of the subterranean vault 1808.

In some examples, at least a portion of the ground loop 1908 is disposed below the frost line of the ground as represented in FIG. 19. The temperature of the soil below the frost line is more stable because it is not susceptible to freezing. The temperature of the soil below the frost line is also typically more mild (e.g., 50-65° F. (10-18° C.)). In the illustrated example, the ground loop 1908 is configured as a vertical loop that extends vertically up and down in the ground. In other examples, the ground loop 1908 can be configured as a horizontal loop or a slinky loop. In the illustrated example, the ground loop 1908 has multiples turns or coils (e.g., serpentines). The ground loop 1908 can include any number of turns or coils. In the illustrated example the ground loop 1908 is below or deeper than the subterranean vault 1808. However, in other examples, at least a portion of the ground loop 1908 can be at the same depth as or higher than the subterranean vault 1808.

In the illustrated example, the geothermal heat pump system 1900 includes example control circuitry 1914 to control the operations the geothermal heat pump system 1900. The example control circuitry 1914 includes example pump control circuitry 1916, example fan control circuitry 1918, example sensor interface circuitry 1920, and example comparator circuitry 1922. The pump control circuitry 1916 controls the operations of the pump 1902, such as causing the pump 1902 to activate or deactivate and/or causing a change in speed of the pump 1902 (e.g., to increase or decrease the flow rate of the cooling/heating fluid). The fan control circuitry 1918 controls the operations of the fan 1906, such as causing the fan 1906 to activate or deactivate and/or causing the speed of the fan 1906 to change. The sensor interface circuitry 1920 receives data indicative of one or more parameters or parameter values being monitored. For example, the sensor interface circuitry 1920 may receive temperature measurements from one or more temperature sensors. In the illustrated example, the geothermal heat pump system 1900 includes a first temperature sensor 1924 to measure the ambient air in the subterranean vault 1808, a second temperature sensor 1926 to measure the temperature of the fluid entering the radiator 1904, a third temperature sensor 1928 to measure the temperature of the fluid exiting the radiator 1904, a fourth temperature sensor 1930 to measure the temperature of the fluid in the ground loop 1908, and a fifth temperature sensor 1932 to measure the temperature of the edge servers 1802. In other examples, the geothermal heat pump system 1900 can include additional or fewer temperature sensors and/or the sensor(s) can be disposed in other locations than shown in FIG. 19. In some examples, the temperature sensors 1924-1932 are implemented as thermocouples. The comparator circuitry 1922 compares the parameter(s) or parameter value(s) to one or more thresholds. For example, the comparator circuitry 1922 compares the temperature measurements to one or more temperature thresholds. Based on the comparison(s), the pump control circuitry 1916 and the fan control circuitry 1918 control performance of the pump 1902 and/or the fan 1906, respectively, to increase or decrease the heating or cooling (e.g., cause activation, deactivation, and/or change an operational speed of the pump 1902 and/or the fan 1906). In some examples, the fifth temperature sensor 1932 includes multiple temperature sensors for different ones of the edge servers 1802. If one or more of the edge servers 1802 demands more cooling/heating, the geothermal heat pump system 1900 can be activated and/or adjusted to meet the desired heating/cooling demands. For example, a first edge server may operate efficiently below a temperature 60° F., while other servers may operate efficiently below a temperature 70° F. The geothermal heat pump system 1900 can be operated to achieve 60° F. cooling for the first edge server. As another example, the measured parameter may include power usage of the edge servers 1802. For example, the sensor interface circuitry 1920 can receive a signal (e.g., at a periodic interval) from the edge servers 1802 indicating the power usage of the edge servers 1802. The comparator circuitry 1922 compares the power usage to a threshold. If, for example, the power usage exceeds the threshold, the pump control circuitry 1916 can activate and/or increase the speed of the pump 1902 to provide more cooling to the subterranean vault 1808.

As another example, the parameter may include the workload(s) of the edge servers 1802. The workloads of the edge servers 1802 may increase or decrease over time. If the workload is relatively high or increasing, the geothermal heat pump system 1900 can be activated and/or adjusted to provide additional cooling. In some examples, the sensor interface circuitry 1920 receives data indicative of the workloads from the edge servers 1802. In some examples, the sensor interface circuitry 1920 determines the workload(s) based on one or more Service Level Agreements (SLAs), which may outline the amount of computing power needed at certain times for certain customers. In some examples, the sensor interface circuitry 1920 can determine the workload and/or estimated workload duration to determining upcoming heating/cooling demands. Based on these demands, the geothermal heat pump system 1900 can increase or decrease heating/cooling to meet the demands. For example, the control circuitry 1914 knows the current workload and the estimated future workload, and controls the configuration based on these factors. In some examples, certain types of workloads (e.g., machine learning applications) utilize more power and therefore generate more heat. Depending on the type of workload, the geothermal heat pump system 1900 can be activated and/or adjusted. Therefore, the control circuitry 1914 actively monitors one or more parameters or parameter values and controls the geothermal heat pump system 1900 to ensure the edge servers 1802 are properly and efficiently heated and/or cooled. In some examples, the control circuitry 1914 includes a transmitter to transmit (e.g., via telemetry) any of the parameter or parameter values (e.g., temperatures, workloads, etc.) to an orchestration management system or layer.

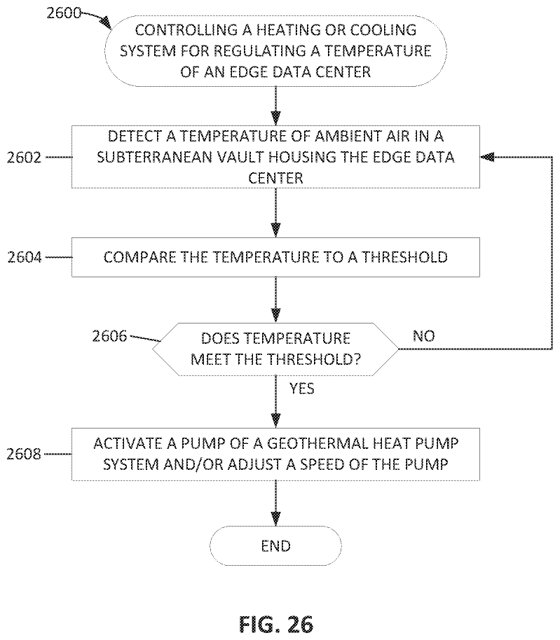

The control circuitry 1914 of FIG. 19 may be instantiated (e.g., creating an instance of, bring into being for any length of time, materialize, implement, etc.) by processor circuitry such as a central processing unit executing instructions. Additionally or alternatively, the control circuitry 1914 of FIG. 19 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 19 may, thus, be instantiated at the same or different times. Some or all of the circuitry may be instantiated, for example, in one or more threads executing concurrently on hardware and/or in series on hardware. Moreover, in some examples, some or all of the circuitry of FIG. 19 may be implemented by microprocessor circuitry executing instructions to implement one or more virtual machines and/or containers. Further, any of the example circuitry of the example control circuitry 1914 can be instantiated by processor circuitry executing instructions and/or configured to perform operations such as those represented by the flowchart of FIG. 26.

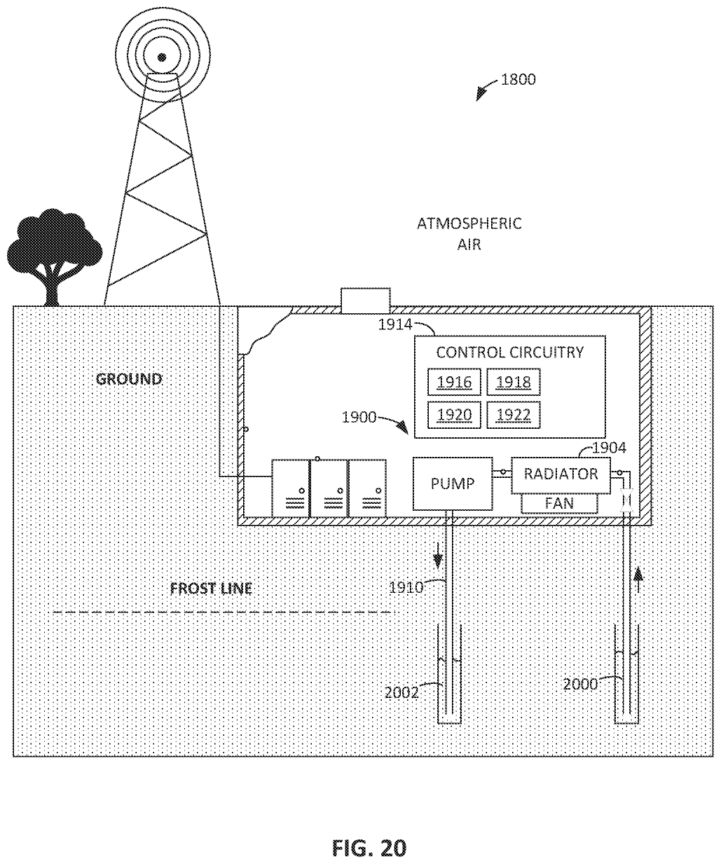

In the illustrated example of FIG. 19, the geothermal heat pump system 1900 is a closed loop system. In particular, the same fluid is continuously cycled through the fluid circuit 1910. In other examples, the geothermal heat pump system 1900 can be implemented as an open loop system. For example, FIG. 20 shows an example in which geothermal heat pump system 1900 is an open loop system. In the illustrated example of FIG. 20, the fluid circuit 1910 draws fluid (e.g., ground water) from a first well 2000 and, after flowing through the radiator 1904, dispels the fluid to a second well 2002. The first and second wells 2000, 2002 may be different water sources or part of the same water source (e.g., an aquifer). Similarly, in other examples the geothermal heat pump system 1900 can be implemented as an open loop system that uses water from a pond, lake, or other body of water.

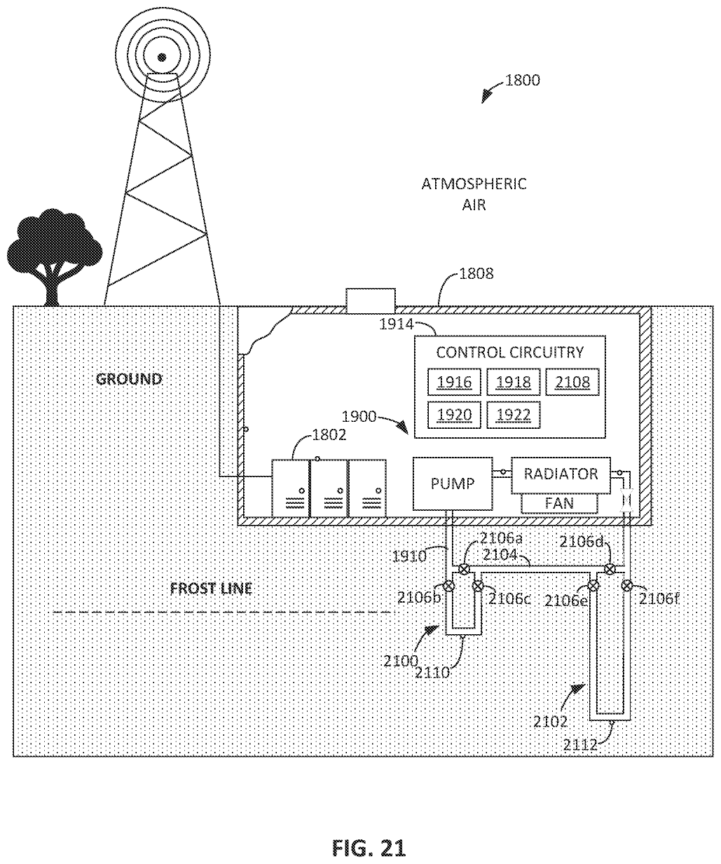

In some examples, the geothermal heat pump system 1900 can utilize different pipes or zones with different temperatures. For example, as shown in FIG. 21, the geothermal heat pump system 1900 includes a first ground loop 2100 and a second ground loop 2102 connected by a distribution or mixing pipe section 2104 of the fluid circuit 1910. The geothermal heat pump system 1900 includes one or more valves 2106a-2106f to regulate the flow of fluid through the first and second ground loops 2100, 2102. In some examples, the first ground loop 2100 is capable of heating or cooling to a first temperature and the second ground loop 2102 is capable of heating or cooling to a second temperature different than the first temperature. For example, the first and second ground loops 2100, 2102 may have a different number of turns and/or may extend to different depths into the ground. Therefore, the first and second ground loops 2100, 2102 are capable of heating or cooling the fluid to different temperatures. In the example of FIG. 21, the control circuitry 1914 includes example valve control circuitry 2108. The valve control circuitry 2108 can cause certain ones of the valves 2106a-2106f to open or close to utilize fluid from the first and/or second ground loops 2100, 2102 to achieve a desired temperature in the subterranean vault 1808. For example, the valve control circuitry 2108 can cause the valve 2106a to close and cause the valves 2106b, 2106c to open, which causes the fluid to be pumped through the first ground loop 2100. The valve control circuitry 2108 can also control operation of the valves 2106a-2106f to mix fluid from both the ground loops 2100, 2102. While in this example there are two ground loops 2100, 2102, the geothermal heat pump system 1900 can include any number of ground loops (e.g., three, four, five, etc.) to achieve different levels of heating/cooling.

In some examples, the first and second ground loops 2100, 2102 may be considered storage tanks because the fluid may sit idle in the first and second ground loops 2100, 2102 for a period of time. The control circuitry 1914 can operate the valves 2106a-2106f to draw from one or both of the storage tanks as needed to achieve a desired temperature in the subterranean vault 1808. In the illustrated example, the geothermal heat pump system 1900 includes a first temperature sensor 2110 to measure the temperature of the fluid in the first ground loop 2100 (a first storage tank) and a second temperature sensor 2112 to measure the temperature of the fluid in the second ground loop 2102 (a second storage tank). Based on the temperature of the fluid in the first and second ground loops 2100, 2102, and the desired temperature in the subterranean vault 1808, the control circuitry 1914 can open and close the valves 2106a-2106f to create and target temperature fluid for achieving the desired temperature in the subterranean vault 1808. In some examples, the temperature sensors 2110, 2112 are thermocouples. In some examples, the temperature sensors 2110, 2112 transmit measurements to the controller 214 wirelessly via a Message Queuing Telemetry Transport (MQTT) broker or provider, which is a messaging protocol used to communicate with remote Internet of Things (IoT) devices. In other examples, the temperature sensors 2110, 2112 may be other types of sensors and/or communicate via other message protocols. In some examples, based on the temperatures of the ground loops 2100, 2102, the control circuitry 1914 can partially or fully open the valves to obtain a certain amount of flow to achieve the desired temperature in the subterranean vault 1808.

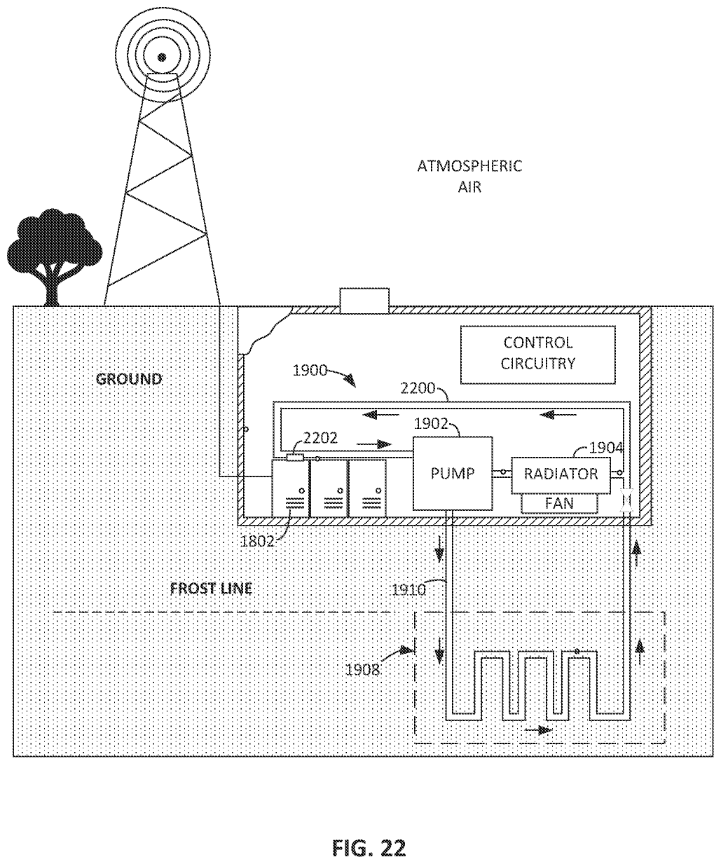

In some examples, in addition to or as an alternative to routing the fluid through the radiator 1904, the geothermal heat pump system 1900 can route the fluid to the edge servers 1802 for direct or indirect heating and/or cooling. For example, as shown in FIG. 22, the fluid circuit 1910 includes a secondary circuit 2200 (which may also be referred to as a secondary loop) that routes the fluid from the ground loop 1908 to the edge servers 1802 and then back to the pump 1902. At the edge servers 1802, the fluid may be directed through one or more devices 2202, such through as one or more cold plates, through one or more heat exchangers, or into one or more immersion cooling tanks in which the electronic components are disposed. Examples of these devices are disclosed above in connection with FIGS. 1-16. Each of the edge servers 1802 can include a metal housing, which may be dimensioned to house the electronic components and/or cooling components (e.g. the device 2202). In some examples, the devices 2202 (e.g., cooling plates, heat exchangers) are coupled (e.g., bolted) onto the corresponding housings of the edge servers 1802 and/or disposed near the housings of the edge server 1802 (e.g., the device 2202 can be a heat exchanger with a fan near an edge server). In some examples, the secondary circuitry 2200 can include one or more valves to route fluid to specific ones of the device 2202 based on the workload and/or sensed temperature of the corresponding edge server 1802. Each of the edge servers 1802 depicted in FIGS. 18-25 can be a common structure with multiple servers or separate structures with separate bays of servers.

In some examples, the secondary circuit 2200 is configured to take advantage of different temperature demands. For example, the secondary circuit 2200 may route the fluid to a first edge server 1802 with a higher cooling demand that causes an increase in temperature from 10° C. to 20° C., and then routes the 20° C. fluid to a second edge server 1802 with a lower cooling demand (e.g., a storage sled). After cooling multiple edge servers 1802, the fluid can be returned to ground loop 1908 for cooling. In some examples, at interim locations where additional thermal control is desired (e.g., between systems on a rack), one or more cold plates can be allied to the coolant line or additional coolant may be added to the flow. Therefore, flows of different temperatures can optimized the coolant temperature for its next location.

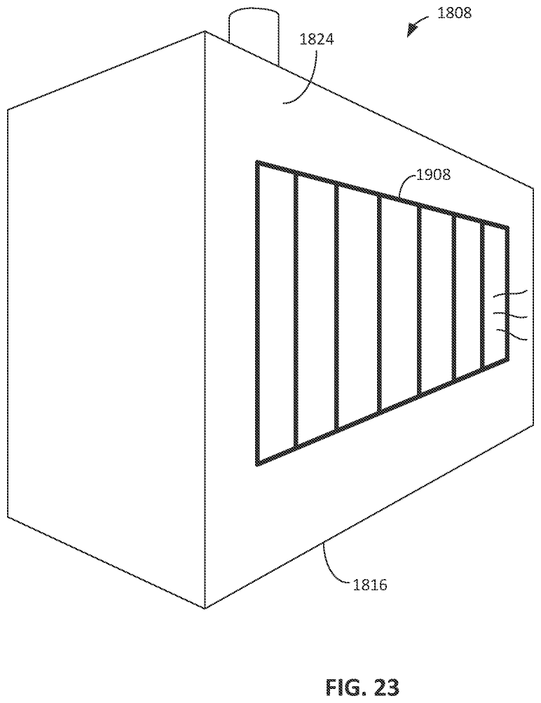

FIG. 23 is a perspective view of the subterranean vault 1808. In this example, the ground loop 1908 is disposed on an exterior side of the side wall 1824 of the subterranean vault 1808. When the subterranean vault 1808 is disposed in the ground, the ground loop 1908 is in contact with the soil in the ground surrounding the subterranean vault 1808. This enables the subterranean vault 1808 and the ground loop 1908 to be constructed as a single unit that can be easily installed in the ground. Additionally or alternatively, in other examples, the ground loop 1908 can be disposed on the bottom wall 1816 of the subterranean vault 1808, such that the ground loop 1908 is disposed below the subterranean vault 1808 when installed in the ground. In some examples, the subterranean vault 1808 can have loops on multiple sides of the vault 1808. For example, a first ground loop can be on an exterior side of the first side wall 1818, a second ground loop can be on an exterior of the second side wall 1820, etc. Similar to the multi-loops system disclosed in connection with FIG. 21, the geothermal heat pump system 1900 can utilize one or more of the loops depending on the cooling/heating demands. Further, in some examples, in addition to the ground loops on the sides of the subterranean vault 1808, one or more ground loops can be disposed in the ground below the subterranean vault 1808, as shown in FIG. 19.

In other examples, the coils or loop shown in FIG. 23 may correspond to the radiator 1904, which heats or cools the inside of the subterranean vault 1808. The radiator 1904 is fluidly coupled to the ground loop 1908 further in the ground and/or another type of external heat exchanger. In some examples, the coils or loop dissipates and/or absorbs heat via passive radiation.

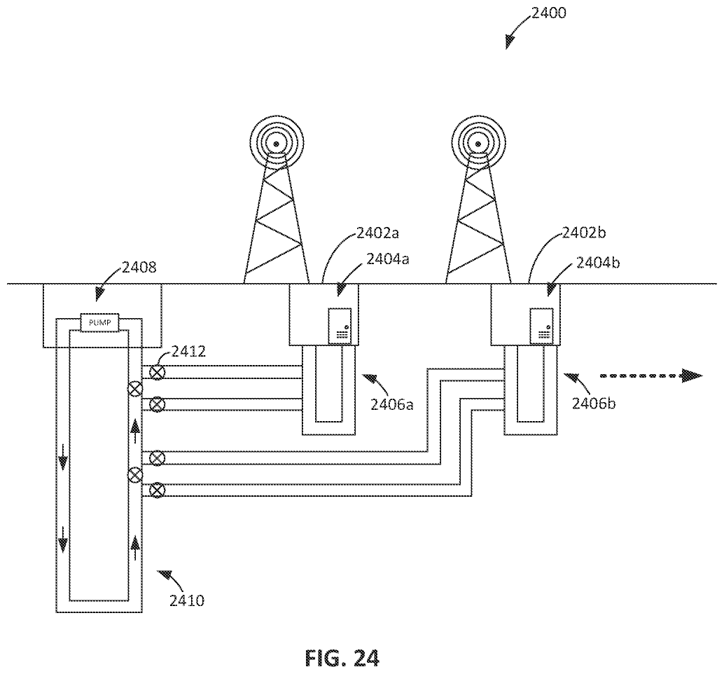

In some examples, such as in a populated or dense area are having multiple edge data centers, a centralized heating/cooling unit can be used to distribute supplemental flow to one or more of the edge data centers. For example, FIG. 24 shows an example network or system 2400 that includes a first subterranean vault 2402a with a first edge data center 2404a and a first geothermal heat pump system 2406a, and a second subterranean vault 2402b with a second edge data center 2404b and a second geothermal heat pump system 2406b. The first and second subterranean vaults 2402a, 2402b may be similar any of the subterranean vaults 1800 disclosed herein. The edge data centers 2404a, 2404b may be deployed in a relatively dense arrangement in an area with a high amount of activity, such as in or around a city. While in this example only two edge data centers are shown, the system 2400 may include any number of edge data centers.

In the illustrated example, the system 2400 includes a supplemental geothermal heat pump system 2408 with a ground loop 2410. The system 2400 includes one or more valves 2412 (one of which is referenced in FIG. 7) that enable the supplemental geothermal heat pump system 2408 to provide (e.g., additional) fluid flow to the first and/or second geothermal heat pump systems 2406a, 2406b. For example, if there is a higher heating or cooling demand at the first edge data center 2404a, certain ones of the valves 2412 can be opened to enable additional fluid flow from the supplemental geothermal heat pump system 2406 to the first geothermal heat pump system 2406a. Thus, in the example of FIG. 24, the supplemental geothermal heat pump system 2408 helps regulate the temperature in the first subterranean vault 2402a in response to compute demands, environmental conditions, etc. The same can occur in connection with the second subterranean vault 2402b and the second geothermal heat pump system 2406b. In some instances, the ambient air temperature at the first and second subterranean vaults 2402a, 2402b may be different (e.g., one of the subterranean vaults is in a shaded area). Further, the edge data centers 2404a, 2404b may experience different power usages/loads at different times. Therefore, the auxiliary geothermal heat pump system 2408 can be used to supply supplemental flow at different times based on demand (e.g., amount of coolant flow per second at a given temperature or a nominal amount of thermal dissipation). As mentioned above, the system 2400 can include any number of edge server deployment locations. In some examples, the auxiliary geothermal heat pump system 2408 is disposed centrally between one or more of the edge data centers.

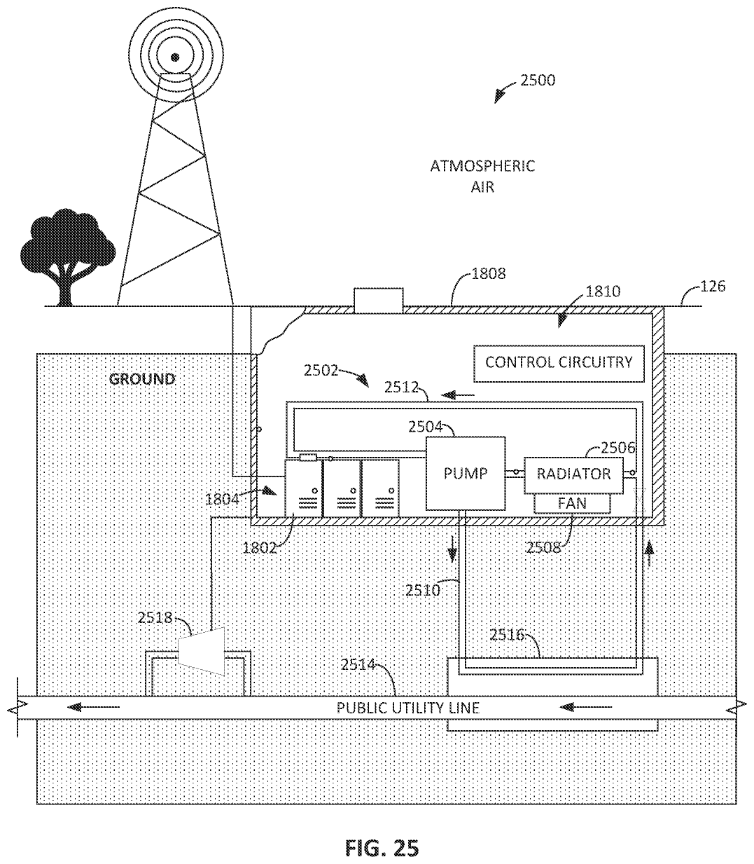

FIG. 25 illustrates an example system 2500 including the edge data center 1804 in the subterranean vault 1808. The system 2500 includes an example heat transfer system 2502 (which may also be referred to as a heat transfer loop, temperature control system, or heat pump system) to regulate the temperature in the internal area 1810 of the subterranean vault 1808 and/or provide fluid for heating and/or the edge servers 1802 of the edge data center 1804. The heat transfer system 2502 is similar to the geothermal heat pump system 1900 disclosed herein and includes a pump 2504, a radiator 2506, a fan 2508, and a fluid circuit 2510 to provide fluid through the radiator 2506 (for controlling the ambient air temperature) and/or through a secondary circuit 2512 to the edge servers 1802 of the edge data center 1804. As disclosed above, the secondary circuitry 2512 can route the fluid through one or more colds plates, through one or more heat exchangers, or into one or more immersion cooling tanks. However, in this example, the heat transfer system 2502 utilizes a public utility line as a heat sink for the primary heating/cooling loop. For example, as shown in FIG. 25, a public utility line 2514 is disposed (e.g., buried) in the ground. The public utility line 2514 can be any type of local or municipal utility line with flowing fluid. In this example, the public utility line 2514 is a public water main, referred to herein as the public water main 2514. The public water main 2514 is an underground pipe in a municipal water distribution system that carries water to various homes and businesses. Public water mains typically have a high flow rate (e.g., 1000 gallons-per-minute GPM (or higher or lower depending on the location from the source)) that remains relatively constant all year long and is at a relatively constant temperature (e.g., 60° F.). Therefore, the public water main 2514 is a reliable source of heating or cooling for the edge data center 1804. In some examples, it is beneficial to use a public water main that has at least 200 GPM to provide sufficient heating/cooling for the heat transfer system 2502, but may be higher or lower depending on the size of the edge data center and the heating/cooling demands. In other examples, the heat transfer system 2502 can be tied into another type of public utility line with flowing fluid, such as a storm drain, a sewage line, or a natural gas line.

In the illustrated example of FIG. 25, the heat transfer system 2502 includes a heat exchanger 2516 coupled to the public water main 2514. The fluid circuit 2510 directs the fluid through the heat exchanger 2516 to exchange heat between the fluid of the heat transfer system 2502 and the water in the public water main 2514. The heat exchanger 2516 is hermetically sealed. As such, that the water in the public water main 2514 is not mixed with and/or contaminated by the fluid in the fluid circuit 2510. In other words, the two fluids remain completely isolated and separate.

Assuming the system 2500 is deployed in a relative warm environment, as the fluid in the fluid circuitry 2510 flows through the heat exchanger 2516, heat is transferred to the water in the public water main 2514, thereby cooling the fluid in the fluid circuit 2510. The cooled fluid is then pumped to the radiator 2506 for cooling the air in the subterranean vault 1808 and/or pumped to the secondary circuitry 2512 for direct and/or indirect cooling of the edge servers 1802. As mentioned above, public water mains typically have a high flow rate. As such, any heat transfer to the public water main 2514 would be relatively minor (e.g., an increase of less than about 9° F. (5° C.)), and typically the water temperature cools back to the ground temperature before reaching any downstream locations. Conversely, if the system 2500 is deployed in a relative cold environment, the public water main 2514 can be used to warm the fluid in the fluid circuit 2510.

In some examples, the system 2500 includes a turbine 2518 operably coupled to receive at least a portion of the water flow through the public water main 2514 (sometimes referred to as in-pipe hydroelectric). The turbine 2518 converts the power of the flowing water into electrical power that can be used by the electronic components in the subterranean vault 1808. As such, the electrical power and the heating/cooling can both be provided to the subterranean vault 1808 from the public water main 2514.

While the example heating/cooling systems of FIGS. 18-25 are shown in connection with an edge data center in a subterranean vault, the example heating/cooling systems can also be used in connection with data centers that are above-ground. Further, while the examples of FIGS. 18-25 are described in connection with data centers for edge computing, the example vaults and heating/cooling systems can be used in connection with other types of data centers or computing networks.

While an example manner of implementing the control circuitry 1914 of FIG. 19 is illustrated in FIGS. 19-25, one or more of the elements, processes, and/or devices illustrated in FIGS. 19-25 may be combined, divided, re-arranged, omitted, eliminated, and/or implemented in any other way. Further, the example pump control circuitry 1916, the example fan control circuitry 1918, the example sensor interface circuitry 1920, the example comparator circuitry 1922, the example valve control circuitry 2180, and/or, more generally, the example control circuitry 1914 of FIGS. 19-22, may be implemented by hardware alone or by hardware in combination with software and/or firmware. Thus, for example, any of the example pump control circuitry 1916, the example fan control circuitry 1918, the example sensor interface circuitry 1920, the example comparator circuitry 1922, the example valve control circuitry 2180, and/or, more generally, the example control circuitry 1914, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example control circuitry 1914 of FIG. 19 may include one or more elements, processes, and/or devices in addition to, or instead of, those illustrated in FIG. 19, and/or may include more than one of any or all of the illustrated elements, processes and devices.

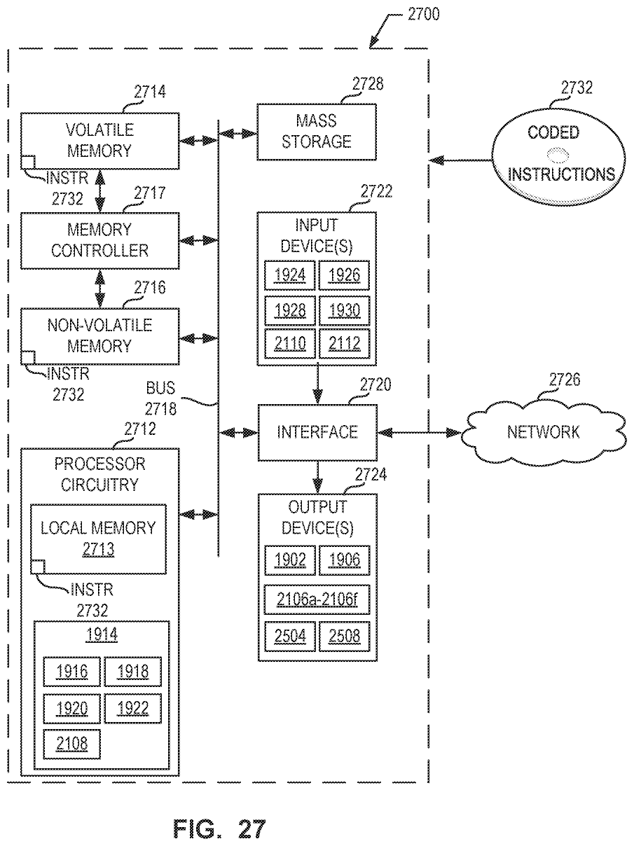

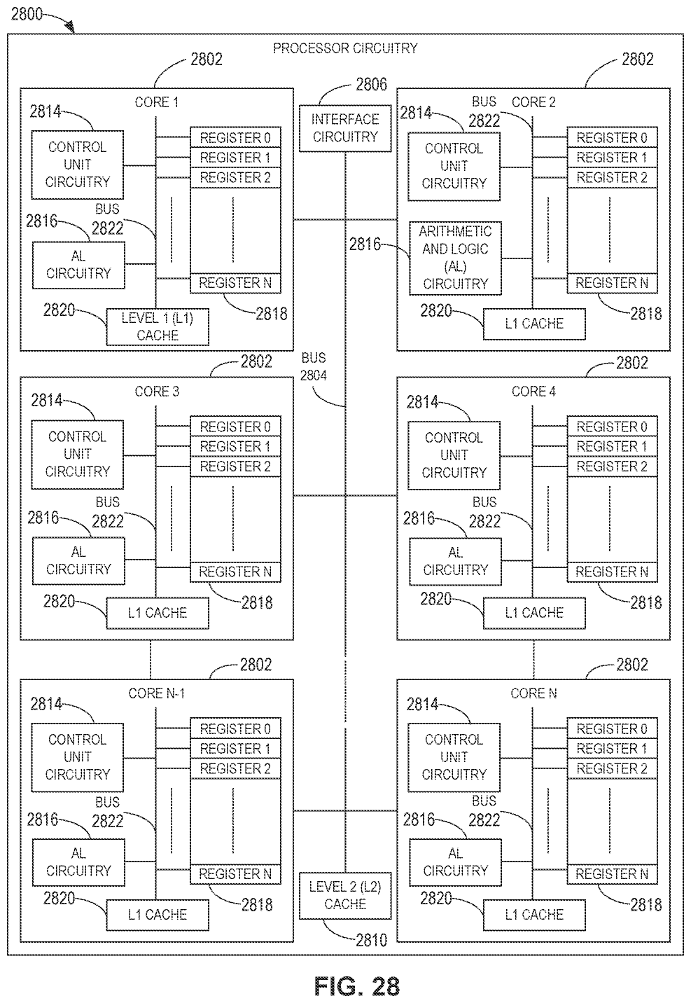

A flowchart representative of example machine readable instructions, which may be executed to configure processor circuitry to implement the controller of FIG. 19, is shown in FIG. 26. The machine readable instructions may be one or more executable programs or portion(s) of an executable program for execution by processor circuitry, such as the processor circuitry 2712 shown in the example processor platform 2700 discussed below in connection with FIG. 27 and/or the example processor circuitry discussed below in connection with FIGS. 28 and/or 29. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowchart illustrated in FIG. 26, many other methods of implementing the example control circuitry 1914 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 26 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 26 is a flowchart representative of example machine readable instructions and/or example operations 2600 that may be executed and/or instantiated by processor circuitry to control a heating or cooling system for regulating the temperature of an edge data center. The example machine readable instructions and/or the operations 2600 of FIG. 26 are described in connection with the geothermal heat pump system 1900 disclosed in connection with FIG. 19. However, the example machine readable instructions and/or the operations 2600 of FIG. 26 can be similarly implemented in connection with any of the other systems disclosed in connection with FIGS. 20-25.

The machine readable instructions and/or the operations 2600 of FIG. 26 begin at block 2602, at which the sensor interface circuitry 1920 detects a temperature of ambient air in the subterranean vault 1808. For example, the sensor interface circuitry 1920 receives sensor signals output by the first temperature sensor 1924 and determines the temperature of the ambient air based on the sensor signals.

At block 2604, the comparator circuitry 1922 compares the temperature to a threshold. At block 2606, the comparator circuitry 1922 determines whether the temperature meets (e.g., exceeds, falls below, etc.) the threshold. In some examples, such when the system is used to cool the edge data center 1804, the threshold may be an upper limit. For example, the threshold may be 80° F. (27° C.), and the comparator circuitry 1922 compares the temperature to the threshold to determine if the temperature exceeds the threshold. In other examples, such as when the system is used to warm the edge data center 1804, the threshold may be a lower limit. For example, the threshold may be 50° F. (10° C.), and the comparator circuitry 1922 compares the temperature to the threshold to determine if the temperature has fallen below the threshold. If the temperature does not meet the threshold, control proceeds back to block 2602 and the operations are repeated.

If the temperature meets the threshold (e.g., exceeds the threshold, falls below the threshold, etc.), the pump control circuitry 1916, at block 2608, cause at least one of activation the pump 1902 or adjustment to (e.g., an increase of) the speed of the pump 1902. This causes increased flow through the fluid circuit 1910, which is used to regulate (e.g., increase or decrease) the temperature of the ambient air in the subterranean vault 1808 to a desired or target temperature. In some examples, once the temperature of the ambient air reaches a desired temperature, the pump control circuitry 1916 causes the pump 1902 to deactivate or the speed of the pump 1902 to be reduced. Additionally or alternatively, the control circuitry 1914 can cause activation of the pump 1902 and/or adjustment to the speed of the pump 1902 based on temperature measurements from one or more other locations (e.g., in the ground loop 1908, the atmospheric air above ground, etc.). In some examples, the fan control circuitry 1918 causes activation of the fan 1906 and/or adjustment to the speed of the fan 1906 to direct the ambient air across the radiator 1904. Additionally or alternatively, the control circuitry 1914 can cause activation of the pump 1902 and/or adjustment to the speed of the pump 1902 based one or more other parameters, such as a power usage of the edge data center 1804.

FIG. 27 is a block diagram of an example processor platform 2700 structured to execute and/or instantiate the machine readable instructions and/or the operations of FIG. 26 to implement the control circuitry 1914 of FIG. 19. The processor platform 2700 can be, for example, a server, a personal computer, a workstation, a machine learning system (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing device.

The processor platform 2700 of the illustrated example includes processor circuitry 2712. The processor circuitry 2712 of the illustrated example is hardware. For example, the processor circuitry 2712 can be implemented by one or more integrated circuits, logic circuits, FPGAs, microprocessors, CPUs, GPUs, IPUs, DPUs, DSPs, and/or microcontrollers from any desired family or manufacturer. The processor circuitry 2712 may be implemented by one or more semiconductor based (e.g., silicon based) devices. In this example, the processor circuitry 2712 implements the pump control circuitry 1916, the fan control circuitry 1918, the sensor interface circuitry 1920, the comparator circuitry 1922, and the example valve control circuitry 2108 of the control circuitry 1914.

The processor circuitry 2712 of the illustrated example includes a local memory 2713 (e.g., a cache, registers, etc.). The processor circuitry 2712 of the illustrated example is in communication with a main memory including a volatile memory 2714 and a non-volatile memory 2716 by a bus 2718. The volatile memory 2714 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2716 may be implemented by flash memory and/or any other desired type of memory device. Access to the main memory 2714, 2716 of the illustrated example is controlled by a memory controller 2717.

The processor platform 2700 of the illustrated example also includes interface circuitry 2720. The interface circuitry 2720 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 2722 are connected to the interface circuitry 2720. The input device(s) 2722 permit(s) a device and/or a user to enter data and/or commands into the processor circuitry 2712. In this example, the input device(s) 2722 can include any of the example temperature sensors 1924-1932, 2110, 2122. Additionally or alternatively, the input device(s) 2722 can be implemented by, for example, an audio sensor, a microphone, a camera (still or video), a keyboard, a button, a mouse, a touchscreen, a track-pad, a trackball, an isopoint device, and/or a voice recognition system.

One or more output devices 2724 are also connected to the interface circuitry 2720 of the illustrated example. In this example, the output device(s) 2724 can include the pump 1902, the fan 1906, the valves 2106a-2106f, the pump 2504, and/or the fan 2508. Additionally or alternatively, the output device(s) 2724 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2720 of the illustrated example, thus, typically includes a graphics driver card, a graphics driver chip, and/or graphics processor circuitry such as a GPU.

The interface circuitry 2720 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2726. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 2700 of the illustrated example also includes one or more mass storage devices 2728 to store software and/or data. Examples of such mass storage devices 2728 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine readable instructions 2732, which may be implemented by the machine readable instructions of FIG. 26, may be stored in the mass storage device 2728, in the volatile memory 2714, in the non-volatile memory 2716, and/or on a removable non-transitory computer readable storage medium such as a CD or DVD.

FIG. 28 is a block diagram of an example implementation of the processor circuitry 2712 of FIG. 27. In this example, the processor circuitry 2712 of FIG. 27 is implemented by a microprocessor 2800. For example, the microprocessor 2800 may be a general purpose microprocessor (e.g., general purpose microprocessor circuitry). The microprocessor 2800 executes some or all of the machine readable instructions of the flowchart of FIG. 26 to effectively instantiate the circuitry of FIG. 19 as logic circuits to perform the operations corresponding to those machine readable instructions. In some such examples, the circuitry of FIG. 19 is instantiated by the hardware circuits of the microprocessor 2800 in combination with the instructions. For example, the microprocessor 2800 may be implemented by multi-core hardware circuitry such as a CPU, a DSP, a GPU, an XPU, etc. Although it may include any number of example cores 2802 (e.g., 1 core), the microprocessor 2800 of this example is a multi-core semiconductor device including N cores. The cores 2802 of the microprocessor 2800 may operate independently or may cooperate to execute machine readable instructions. For example, machine code corresponding to a firmware program, an embedded software program, or a software program may be executed by one of the cores 2802 or may be executed by multiple ones of the cores 2802 at the same or different times. In some examples, the machine code corresponding to the firmware program, the embedded software program, or the software program is split into threads and executed in parallel by two or more of the cores 2802. The software program may correspond to a portion or all of the machine readable instructions and/or operations represented by the flowchart of FIG. 26.

The cores 2802 may communicate by a first example bus 2804. In some examples, the first bus 2804 may be implemented by a communication bus to effectuate communication associated with one(s) of the cores 2802. For example, the first bus 2804 may be implemented by at least one of an Inter-Integrated Circuit (I2C) bus, a Serial Peripheral Interface (SPI) bus, a PCI bus, or a PCIe bus. Additionally or alternatively, the first bus 2804 may be implemented by any other type of computing or electrical bus. The cores 2802 may obtain data, instructions, and/or signals from one or more external devices by example interface circuitry 2806. The cores 2802 may output data, instructions, and/or signals to the one or more external devices by the interface circuitry 2806. Although the cores 2802 of this example include example local memory 2820 (e.g., Level 1 (L1) cache that may be split into an L1 data cache and an L1 instruction cache), the microprocessor 2800 also includes example shared memory 2810 that may be shared by the cores (e.g., Level 2 (L2 cache)) for high-speed access to data and/or instructions. Data and/or instructions may be transferred (e.g., shared) by writing to and/or reading from the shared memory 2810. The local memory 2820 of each of the cores 2802 and the shared memory 2810 may be part of a hierarchy of storage devices including multiple levels of cache memory and the main memory (e.g., the main memory 2714, 2716 of FIG. 27). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 2802 may be referred to as a CPU, DSP, GPU, etc., or any other type of hardware circuitry. Each core 2802 includes control unit circuitry 2814, arithmetic and logic (AL) circuitry (sometimes referred to as an ALU) 2816, a plurality of registers 2818, the local memory 2820, and a second example bus 2822. Other structures may be present. For example, each core 2802 may include vector unit circuitry, single instruction multiple data (SIMD) unit circuitry, load/store unit (LSU) circuitry, branch/jump unit circuitry, floating-point unit (FPU) circuitry, etc. The control unit circuitry 2814 includes semiconductor-based circuits structured to control (e.g., coordinate) data movement within the corresponding core 2802. The AL circuitry 2816 includes semiconductor-based circuits structured to perform one or more mathematic and/or logic operations on the data within the corresponding core 2802. The AL circuitry 2816 of some examples performs integer based operations. In other examples, the AL circuitry 2816 also performs floating point operations. In yet other examples, the AL circuitry 2816 may include first AL circuitry that performs integer based operations and second AL circuitry that performs floating point operations. In some examples, the AL circuitry 2816 may be referred to as an Arithmetic Logic Unit (ALU). The registers 2818 are semiconductor-based structures to store data and/or instructions such as results of one or more of the operations performed by the AL circuitry 2816 of the corresponding core 2802. For example, the registers 2818 may include vector register(s), SIMD register(s), general purpose register(s), flag register(s), segment register(s), machine specific register(s), instruction pointer register(s), control register(s), debug register(s), memory management register(s), machine check register(s), etc. The registers 2818 may be arranged in a bank as shown in FIG. 28. Alternatively, the registers 2818 may be organized in any other arrangement, format, or structure including distributed throughout the core 2802 to shorten access time. The second bus 2822 may be implemented by at least one of an I2C bus, a SPI bus, a PCI bus, or a PCIe bus

Each core 2802 and/or, more generally, the microprocessor 2800 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 2800 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

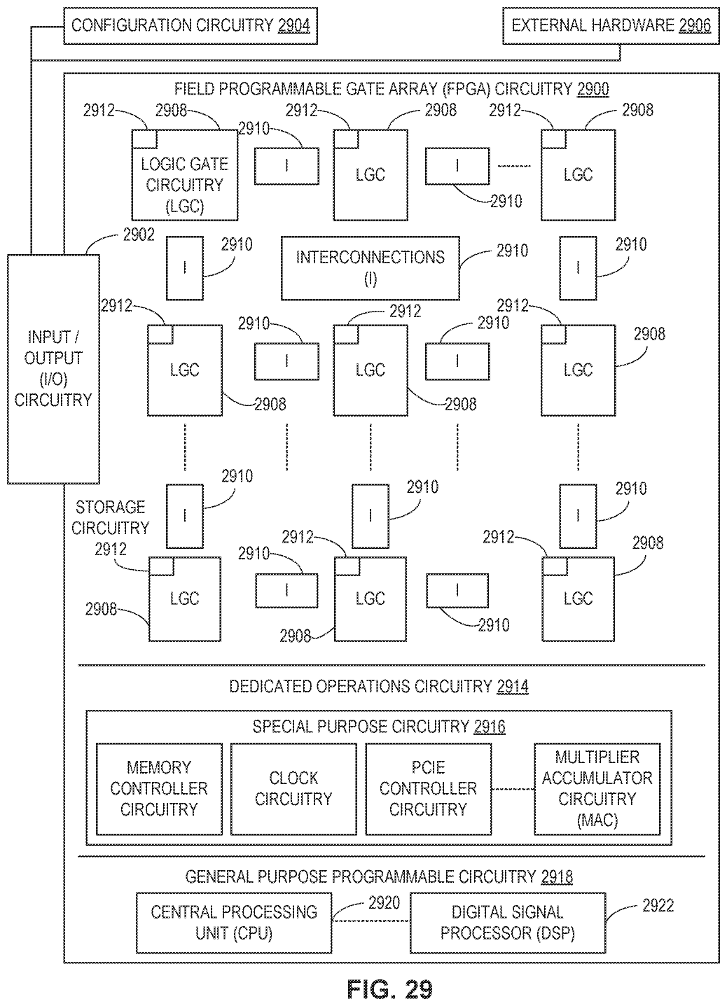

FIG. 29 is a block diagram of another example implementation of the processor circuitry 2712 of FIG. 27. In this example, the processor circuitry 2712 is implemented by FPGA circuitry 2900. For example, the FPGA circuitry 2900 may be implemented by an FPGA. The FPGA circuitry 2900 can be used, for example, to perform operations that could otherwise be performed by the example microprocessor 2800 of FIG. 28 executing corresponding machine readable instructions. However, once configured, the FPGA circuitry 2900 instantiates the machine readable instructions in hardware and, thus, can often execute the operations faster than they could be performed by a general purpose microprocessor executing the corresponding software.

More specifically, in contrast to the microprocessor 2800 of FIG. 28 described above (which is a general purpose device that may be programmed to execute some or all of the machine readable instructions represented by the flowchart of FIG. 26 but whose interconnections and logic circuitry are fixed once fabricated), the FPGA circuitry 2900 of the example of FIG. 29 includes interconnections and logic circuitry that may be configured and/or interconnected in different ways after fabrication to instantiate, for example, some or all of the machine readable instructions represented by the flowchart of FIG. 26. In particular, the FPGA circuitry 2900 may be thought of as an array of logic gates, interconnections, and switches. The switches can be programmed to change how the logic gates are interconnected by the interconnections, effectively forming one or more dedicated logic circuits (unless and until the FPGA circuitry 2900 is reprogrammed). The configured logic circuits enable the logic gates to cooperate in different ways to perform different operations on data received by input circuitry. Those operations may correspond to some or all of the software represented by the flowchart of FIG. 26. As such, the FPGA circuitry 2900 may be structured to effectively instantiate some or all of the machine readable instructions of the flowchart of FIG. 26 as dedicated logic circuits to perform the operations corresponding to those software instructions in a dedicated manner analogous to an ASIC. Therefore, the FPGA circuitry 2900 may perform the operations corresponding to the some or all of the machine readable instructions of FIG. 26 faster than the general purpose microprocessor can execute the same.

In the example of FIG. 29, the FPGA circuitry 2900 is structured to be programmed (and/or reprogrammed one or more times) by an end user by a hardware description language (HDL) such as Verilog. The FPGA circuitry 2900 of FIG. 29, includes example input/output (I/O) circuitry 2902 to obtain and/or output data to/from example configuration circuitry 2904 and/or external hardware 2906. For example, the configuration circuitry 2904 may be implemented by interface circuitry that may obtain machine readable instructions to configure the FPGA circuitry 2900, or portion(s) thereof. In some such examples, the configuration circuitry 2904 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 2906 may be implemented by external hardware circuitry. For example, the external hardware 2906 may be implemented by the microprocessor 2800 of FIG. 28. The FPGA circuitry 2900 also includes an array of example logic gate circuitry 2908, a plurality of example configurable interconnections 2910, and example storage circuitry 2912. The logic gate circuitry 2908 and the configurable interconnections 2910 are configurable to instantiate one or more operations that may correspond to at least some of the machine readable instructions of FIG. 26 and/or other desired operations. The logic gate circuitry 2908 shown in FIG. 29 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2908 to enable configuration of the electrical structures and/or the logic gates to form circuits to perform desired operations. The logic gate circuitry 2908 may include other electrical structures such as look-up tables (LUTs), registers (e.g., flip-flops or latches), multiplexers, etc.

The configurable interconnections 2910 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2908 to program desired logic circuits.

The storage circuitry 2912 of the illustrated example is structured to store result(s) of the one or more of the operations performed by corresponding logic gates. The storage circuitry 2912 may be implemented by registers or the like. In the illustrated example, the storage circuitry 2912 is distributed amongst the logic gate circuitry 2908 to facilitate access and increase execution speed.

The example FPGA circuitry 2900 of FIG. 29 also includes example Dedicated Operations Circuitry 2914. In this example, the Dedicated Operations Circuitry 2914 includes special purpose circuitry 2916 that may be invoked to implement commonly used functions to avoid the need to program those functions in the field. Examples of such special purpose circuitry 2916 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2900 may also include example general purpose programmable circuitry 2918 such as an example CPU 2920 and/or an example DSP 2922. Other general purpose programmable circuitry 2918 may additionally or alternatively be present such as a GPU, an XPU, etc., that can be programmed to perform other operations.

Although FIGS. 28 and 29 illustrate two example implementations of the processor circuitry 2712 of FIG. 27, many other approaches are contemplated. For example, as mentioned above, modern FPGA circuitry may include an on-board CPU, such as one or more of the example CPU 2920 of FIG. 29. Therefore, the processor circuitry 2712 of FIG. 27 may additionally be implemented by combining the example microprocessor 2800 of FIG. 28 and the example FPGA circuitry 2900 of FIG. 29. In some such hybrid examples, a first portion of the machine readable instructions represented by the flowchart of FIG. 26 may be executed by one or more of the cores 2802 of FIG. 28, a second portion of the machine readable instructions represented by the flowchart of FIG. 26 may be executed by the FPGA circuitry 2900 of FIG. 29, and/or a third portion of the machine readable instructions represented by the flowchart of FIG. 26 may be executed by an ASIC. It should be understood that some or all of the circuitry of FIG. 19 may, thus, be instantiated at the same or different times. Some or all of the circuitry may be instantiated, for example, in one or more threads executing concurrently and/or in series. Moreover, in some examples, some or all of the circuitry of FIG. 19 may be implemented within one or more virtual machines and/or containers executing on the microprocessor.

In some examples, the processor circuitry 2712 of FIG. 27 may be in one or more packages. For example, the microprocessor 2800 of FIG. 28 and/or the FPGA circuitry 2900 of FIG. 29 may be in one or more packages. In some examples, an XPU may be implemented by the processor circuitry 2712 of FIG. 27, which may be in one or more packages. For example, the XPU may include a CPU in one package, a DSP in another package, a GPU in yet another package, and an FPGA in still yet another package.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

From the foregoing, it will be appreciated that example systems, methods, apparatus, and articles of manufacture have been disclosed that improve heating and/or cooling of edge data centers, which enables the edge data centers to operate more efficiently. Examples disclosed herein utilize subterranean vaults and/or geothermal heat pump systems that take advantage of the stable ground temperature. Examples disclosed herein also take advantage of public utility lines to provide heating and/or cooling.

Examples and combinations of examples disclosed herein include the following:

Example 1 is a system comprising a subterranean vault to be disposed at least partially below ground level of an environment, an edge data center in the subterranean vault, and a geothermal heat pump system to regulate a temperature of ambient air in the subterranean vault.

Example 2 includes the system of Example 1, wherein the geothermal heat pump system includes a ground loop to be disposed in the ground.

Example 3 includes the system of Example 2, wherein the geothermal heat pump system includes, a pump, a radiator in the subterranean vault, and a fluid circuit to fluidly couple the pump, the radiator, and the ground loop, the fluid circuit containing a fluid.

Example 4 includes the system of claim 3, wherein the fluid is water.

Example 5 includes the system for Example 3, wherein the fluid is a refrigerant, and wherein the geothermal heat pump system includes an expansion valve coupled to the fluid circuit.

Example 6 includes the system of any of Examples 3-5, wherein the geothermal heat pump system includes a fan to direct the ambient air across the radiator.

Example 7 includes the system of any of Examples 3-6, wherein the edge data center includes one or more edge servers, and wherein the fluid circuit includes a secondary circuit to route the fluid to the one or more edge servers.

Example 8 includes the system of Example 7, wherein the secondary circuit is to route the fluid through one or more cold plates, through one or more heat exchangers, or into one or more immersion cooling tanks.

Example 9 includes the system of Examples 7 or 8, wherein the geothermal heat pump system is to be at least one of activated or adjusted based on workloads executed on the edge servers.

Example 10 includes the system of any of Examples 1-9, wherein the subterranean vault is cuboid shaped.

Example 11 includes the system of Example 10, wherein the subterranean vault includes a plurality of walls, the geothermal heat pump system including a ground loop on an exterior side of one of the walls.

Example 12 includes the system of Example 11, wherein the goethermal heat pump system includes multiple ground loops on exterior surfaces of different ones of the walls.

Example 13 includes the system of any of Examples 1-12, wherein the geothermal heat pump system is a closed loop system.

Example 14 includes the system of any of Examples 1-12, wherein the geothermal heat pump system is an open loop system.

Example 15 is a non-transitory machine readable storage medium comprising instructions that, when executed, cause processor circuitry to at least detect a temperature of ambient air in a vault. The vault is disposed at least partially in the ground. The vault houses an edge data center. The vault includes a geothermal heat pump system. The geothermal heat pump system including a pump to drive fluid through a fluid circuit. The instructions, when executed, further cause the processor circuitry to at least compare the temperature to a threshold and, in response to the temperature meeting the threshold, at least one of cause the pump to activate or cause an adjustment of a speed of the pump.

Example 16 includes the non-transitory machine readable storage medium of Example 15, wherein the geothermal heat pump system includes a radiator and a fan in the vault, and the instructions, when executed, cause the processor circuitry to cause the fan to activate to direct the ambient air in the vault across the radiator.

Example 17 includes the non-transitory machine readable storage medium of Examples 15 or 16, wherein the instructions, when execute, cause the processor circuitry to at least one of cause the pump to activate or cause an adjustment to the speed of the pump based on a power usage of the edge data center.

Example 18 includes a system comprising a subterranean vault to be disposed at least partially below ground level of an environment, an edge data center in the subterranean vault, and a heat transfer system to regulate a temperature of ambient air in the subterranean vault. The heat transfer system includes a fluid circuit and a heat exchanger coupled between the fluid circuit and a public utility line.

Example 19 includes the system of Example 18, wherein the public utility line is a public water main.

Example 20 includes the system of Examples 18 or 19, wherein the heat transfer system includes a pump and a radiator in the subterranean vault. The fluid circuit is to fluidly couple the pump, the radiator, and the heat exchanger.

Example 21 includes the system of any of Examples 18-20, wherein the edge data center includes one or more edge servers, and wherein the fluid circuit includes a secondary circuit to route fluid to the one or more of the edge servers.

Example 22 includes the system of Example 21, wherein the secondary circuit is to route the fluid through one or more cold plates, through one or more heat exchangers, or into one or more immersion cooling tanks.

Example 23 is a method comprising detecting a temperature of ambient air in a vault. The vault is disposed at least partially in the ground. The vault houses an edge data center. The vault includes a geothermal heat pump system. The geothermal heat pump system includes a pump to drive fluid through a fluid circuit. The method further includes comparing the temperature to a threshold and, in response to the temperature meeting the threshold, at least one of causing the pump to activate or causing an adjustment of a speed of the pump.

Example 24 includes the method of Example 23, wherein the geothermal heat pump system includes a radiator and a fan in the vault, and the method further includes causing the fan to activate to direct the ambient air in the vault across the radiator.

Example 25 includes the method of Examples 23 or 24, further including at least one of causing the pump to activate or causing an adjustment to the speed of the pump based on a power usage of the edge data center.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. A system comprising:
a subterranean vault to be disposed at least partially below ground level of an environment;
an edge data center in the subterranean vault; and
a geothermal heat pump system to regulate a temperature of ambient air in the subterranean vault.

2. The system of claim 1, wherein the geothermal heat pump system includes a ground loop to be disposed in the ground.

3. The system of claim 2, wherein the geothermal heat pump system includes:
a pump;
a radiator in the subterranean vault; and
a fluid circuit to fluidly couple the pump, the radiator, and the ground loop, the fluid circuit containing a fluid.

4. The system of claim 3, wherein the fluid is water.

5. The system for claim 3, wherein the fluid is a refrigerant, and wherein the geothermal heat pump system includes an expansion valve coupled to the fluid circuit.

6. The system of claim 3, wherein the geothermal heat pump system includes a fan to direct the ambient air across the radiator.

7. The system of claim 3, wherein the edge data center includes one or more edge servers, and wherein the fluid circuit includes a secondary circuit to route the fluid to the one or more edge servers.

8. The system of claim 7, wherein the secondary circuit is to route the fluid through one or more cold plates, through one or more heat exchangers, or into one or more immersion cooling tanks.

9. The system of claim 1, wherein the subterranean vault is cuboid shaped.

10. The system of claim 9, wherein the subterranean vault includes a plurality of walls, the geothermal heat pump system including a ground loop on an exterior side of one of the walls.

11. The system of claim 1, wherein the geothermal heat pump system is a closed loop system.

12. The system of claim 1, wherein the geothermal heat pump system is an open loop system.

13. A non-transitory machine readable storage medium comprising instructions that, when executed, cause processor circuitry to at least:
detect a temperature of ambient air in a vault, the vault disposed at least partially in the ground, the vault housing an edge data center, the vault including a geothermal heat pump system, the geothermal heat pump system including a pump to drive fluid through a fluid circuit;
compare the temperature to a threshold; and
in response to the temperature meeting the threshold, at least one of cause the pump to activate or cause an adjustment of a speed of the pump.

14. The non-transitory machine readable storage medium of claim 13, wherein the geothermal heat pump system includes a radiator and a fan in the vault, and the instructions, when executed, cause the processor circuitry to cause the fan to activate to direct the ambient air in the vault across the radiator.

15. The non-transitory machine readable storage medium of claim 13, wherein the instructions, when execute, cause the processor circuitry to at least one of cause the pump to activate or cause an adjustment to the speed of the pump based on a power usage of the edge data center.

16. A system comprising:
a subterranean vault to be disposed at least partially below ground level of an environment;
an edge data center in the subterranean vault; and
a heat transfer system to regulate a temperature of ambient air in the subterranean vault, the heat transfer system including a fluid circuit and a heat exchanger coupled between the fluid circuit and a public utility line.

17. The system of claim 16, wherein the public utility line is a public water main.

18. The system of claim 16, wherein the heat transfer system includes:
a pump; and
a radiator in the subterranean vault, the fluid circuit to fluidly couple the pump, the radiator, and the heat exchanger.

19. The system of claim 16, wherein the edge data center includes one or more edge servers, and wherein the fluid circuit includes a secondary circuit to route fluid to the one or more of the edge servers.

20. The system of claim 19, wherein the secondary circuit is to route the fluid through one or more cold plates, through one or more heat exchangers, or into one or more immersion cooling tanks.
